(19) United States
(12) Patent Application Publication
(10) Pub. No.: US 2025/0107296 A1
(43) Pub. Date: Mar. 27, 2025

(54) METHOD FOR MANUFACTURING LIGHT-EMITTING DEVICE AND LIGHT-EMITTING DEVICE

(71) Applicant: NICHIA CORPORATION, Anan-shi (JP)

(72) Inventors: Ryo SUZUKI, Tokushima-shi (JP); Masaya MIYAZAKI, Tokushima-shi (JP)

(73) Assignee: NICHIA CORPORATION, Anan-shi (JP)

(21) Appl. No.: 18/892,857

(22) Filed: Sep. 23, 2024

(30) Foreign Application Priority Data
Sep. 25, 2023 (JP) 2023-160198
Dec. 21, 2023 (JP) 2023-216136
Jun. 25, 2024 (JP) 2024-102125

(51) Int. Cl. H01L 33/60; H01L 25/075; H01L 33/56

(52) U.S. Cl. CPC H10H 20/856; H01L 25/0753; H10H 20/854; H10H 20/0362; H10H 20/0363

(57) ABSTRACT

A method for manufacturing a light-emitting device includes: providing a structure including: a substrate including a plurality of positive and negative wiring parts at an upper surface of the substrate, and a light source part disposed on the substrate, the light source part including: an element substrate, and a plurality of light-emitting parts, each of the light-emitting parts including: a semiconductor structure including a first surface facing the element substrate and a second surface positioned at a side opposite to the first surface, and positive and negative electrode parts disposed on the second surface of the semiconductor structure; providing a mold including an upper mold and a lower mold; disposing a first resin part between the upper surface of the substrate and the second surfaces of the semiconductor structures; and removing the element substrate from the light source part.

### CROSS-REFERENCE TO RELATED APPLICATION

This application claims priority to Japanese Patent Application No. 2023-160198, filed on Sep. 25, 2023, Japanese Patent Application No. 2023-216136, filed on Dec. 21, 2023, and Japanese Patent Application No. 2024-102125, filed on Jun. 25, 2024. The entire disclosures of these applications are hereby incorporated by reference in its entirety.

### BACKGROUND

The present disclosure relates to a method for manufacturing a light-emitting device and a light-emitting device.

For example, JP-A 2015-23156 (Kokai) discloses forming a resin member between a light-emitting element and a substrate.

### SUMMARY

One object of certain embodiments of the disclosure is to provide a method for manufacturing a light-emitting device that can have good light emission characteristics, and the light-emitting device.

According to one aspect of the present disclosure, a method for manufacturing a light-emitting device includes providing a structure, the structure including: a substrate including a plurality of positive and negative wiring parts at an upper surface of the substrate, and a light source part being disposed on the substrate, the light source part including an element substrate and a plurality of light-emitting parts, each of the light-emitting parts including a semiconductor structure including a first surface facing the element substrate and a second surface being positioned at a side opposite to the first surface, and positive and negative electrode parts disposed on the second surface of the semiconductor structure, each of the positive and negative electrode parts being electrically connected with a corresponding one of the positive and negative wiring parts of the substrate; providing a mold including an upper mold and a lower mold; disposing a first resin part between the upper surface of the substrate and the second surfaces of the semiconductor structures, the step of disposing the first resin part including: disposing the structure between the upper mold and the lower mold, supplying a resin material into the mold in a state in which an upper surface of the element substrate is covered with a covering member, curing the resin material, and after the curing, removing the covering member; and removing the element substrate from the light source part.

According to another aspect of the present disclosure, a light-emitting device includes a first structure including a substrate, a plurality of light-emitting parts disposed on an upper surface of the substrate, each of the plurality of light-emitting parts having an upper surface, and a first resin part holding the plurality of light-emitting parts and arranged such that the upper surfaces of the light-emitting parts are exposed from the first resin part, the first resin part including: a light-reflecting part having high light reflectivity, and a light-absorbing part disposed on the light-reflecting part, the light-absorbing part having a light absorbance higher than that of the light-reflecting part; and a second structure including: a plurality of wavelength conversion members each disposed a respective one of the light-emitting parts, and a second resin part disposed between adjacent ones of the plurality of wavelength conversion members. The second resin part is disposed on the light-absorbing part.

According to certain embodiments of the disclosure, a method for manufacturing a light-emitting device that can have good light emission characteristics and the light-emitting device can be provided.

### BRIEF DESCRIPTION OF THE DRAWINGS

FIG. 1 is a schematic top view of a light-emitting device according to a first embodiment;

FIG. 2 is a schematic cross-sectional view along line II-II of FIG. 1;

FIG. 3 is a schematic bottom view of a light-emitting part and bonding members of the light-emitting device according to the first embodiment;

FIG. 4A is a schematic top view for describing a step in a method for manufacturing the light-emitting device according to the first embodiment;

FIG. 4B is a schematic cross-sectional view along line IVB-IVB of FIG. 4A;

FIGS. 4C to 6D are schematic cross-sectional views, each describing a step in the method for manufacturing the light-emitting device according to the first embodiment;

FIG. 7 is a schematic top view of a light-emitting device according to a second embodiment;

FIG. 8 is a schematic cross-sectional view along line VIII-VIII of FIG. 7;

FIG. 9 is a schematic cross-sectional view of a light-emitting device according to a third embodiment;

FIG. 10A is a schematic cross-sectional view for describing a step in a method for manufacturing the light-emitting device according to the third embodiment;

FIG. 10B is a schematic top view for describing a step in the method for manufacturing the light-emitting device according to the third embodiment;

FIG. 10C is a schematic cross-sectional view along line XC-XC of FIG. 10B;

FIG. 10D is a schematic top view for describing a step in the method for manufacturing the light-emitting device according to the third embodiment;

FIG. 10E is a schematic cross-sectional view along line XE-XE of FIG. 10D; and

FIGS. 10F and 10G are schematic cross-sectional views, each describing a step in the method for manufacturing the light-emitting device according to the third embodiment.

### DETAILED DESCRIPTION OF EMBODIMENTS

A light-emitting device and a method for manufacturing a light-emitting device according to embodiments of the disclosure will now be described with reference to the drawings. The following embodiments illustrate a light-emitting device and a method for manufacturing a light-emitting device that embody the technical concepts of the invention, but the invention is not limited to the described embodiments. Unless specifically stated, the dimensions, materials, shapes, relative arrangements, and the like of the components according to the embodiments are not intended to limit the scope of the invention, and are merely illustrative examples. The sizes, positional relationships, and the like of the members shown in the drawings may be exaggerated for clarity of description. In the following description, the same names and reference numerals refer to the same or similar members, and a detailed description is omitted as appropriate. End views that show only cross sections may be used as cross-sectional views.

In the following description, terms that indicate specific directions or positions (e.g., “upper,” “lower”, and other terms including such terms) may be used. Such terms, however, are used merely for better understanding of relative directions or positions when referring to the drawings. As long as the relationships are the same, the relative directions or positions according to terms such as “upper,” “lower,” etc., used when referring to the drawings does not necessarily have the same arrangements in drawings, actual products, and the like outside the disclosure. In the specification, when assuming that there are, for example, two members, the positional relationship expressed as “on (or under)” includes the case where the two members are in contact, and the case where the two members are not in contact so that one of the members is positioned above (or below) the other member. In the specification, unless specifically stated, the expression that a member covers an object includes both the case in which the member is in contact with the object and directly covers the object, and the case in which the member indirectly covers the object without being in contact with the object. In the specification, the width, distance, and thickness in a specific direction of a member respectively refer to the maximum values of the width, distance, and thickness in the specific direction. According to the embodiments, the phrase “in a plan view” refers to viewing an object from above. In the specification, the phrase “in a plan view” may be used to illustrate not only a portion directly visible when viewed from above, but also a portion not directly visible when viewed from above. Using the phrase “in a plan view”, the portion not directly visible when viewed from above may be illustrated as if the portion were transparently viewed.

In the drawings below, directions may be indicated along an X-axis, a Y-axis, and a Z-axis. A direction (e.g., a first direction X) along the X-axis indicates a predetermined direction in the light-emitting surface of the light-emitting device according to the embodiment. A direction (e.g., a second direction Y) along the Y-axis indicates a direction orthogonal to the first direction X in the light-emitting surface. The light-emitting surface of the light-emitting device is parallel to the XY-plane. A direction (e.g., a third direction Z) along the Z-axis indicates a direction orthogonal to the light-emitting surface of the light-emitting device.

In the specification, the following terms defined by JIS K 6800 standard are used as terms indicating the cured state of a resin.

A-stage: The initial state of the thermosetting resin formation reaction. A resin in this state is still soluble in some types of solvents, and melts when heated.

B-stage: An intermediate curing state of the thermosetting resin. A resin in this state softens when heated, and swells but does not completely melt or dissolve when brought into contact with some types of solvents.

C-stage: The final state of the curing reaction of the thermosetting resin. A resin in this state is insoluble and infusible; a fully cured thermosetting resin is in this state.

### First Embodiment

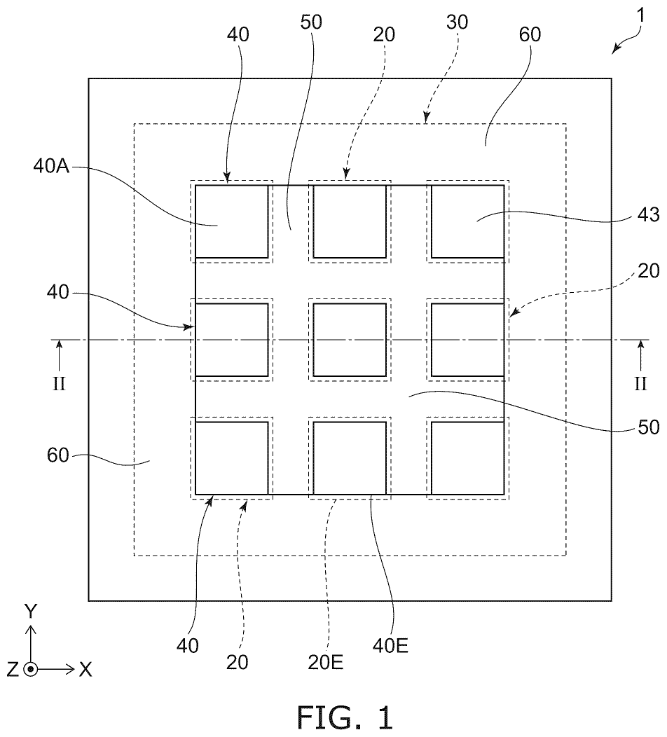

A light-emitting device 1 according to a first embodiment will now be described with reference to FIGS. 1 to 3. The light-emitting device 1 includes a first structure 101 and a second structure 102. The second structure 102 is disposed on the first structure 101.

### First Structure

The first structure 101 includes a substrate 10, a plurality of light-emitting parts 20, and a first resin part 30. The plurality of light-emitting parts 20 are disposed on the substrate 10, and are collectively held by the first resin part 30.

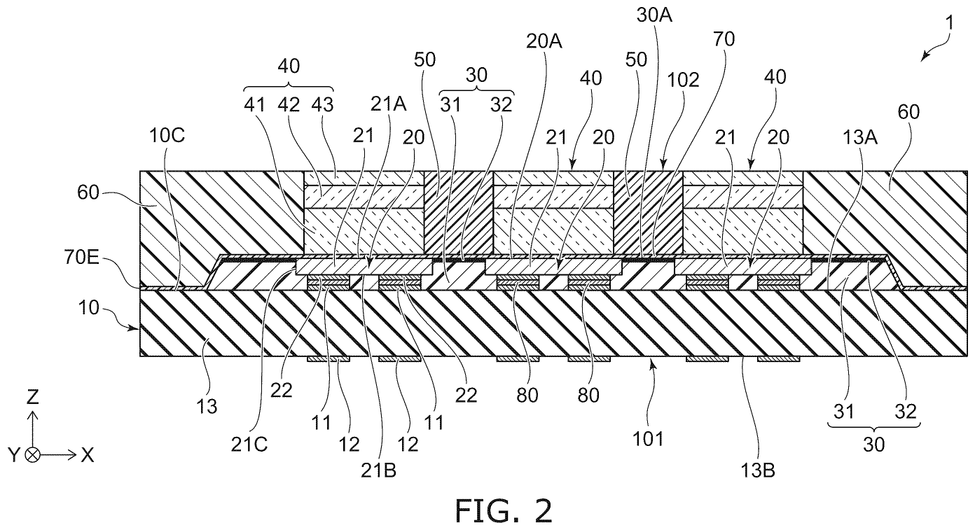

As the plurality of light-emitting parts 20, nine light-emitting parts 20 arranged in a matrix configuration in the first and second directions X and Y are shown in FIG. 1, and three light-emitting parts 20 adjacent to each other in the first direction X are shown in FIG. 2. The arrangement and number of the plurality of light-emitting parts 20 are not limited thereto, and are modifiable according to required light emission characteristics of the light-emitting device 1. For example, the plurality of light-emitting parts 20 may be 5×5 or 7×9 light-emitting parts arranged in a matrix configuration in the first and second directions X and Y.

For example, the light-emitting device 1 can be used as a flash-light source of an imaging device. For example, the imaging device may be mounted in a portable communication terminal. When the light-emitting device 1 is used as a flash-light source of an imaging device, for example, light emission can be switched between a narrow-angle mode in which only the light-emitting part 20 disposed at the center in a plan view emits light, and a wide-angle mode in which all of the light-emitting parts 20 emit light. In the narrow-angle mode, a light illumination angle is smaller than in the wide-angle mode. When the light-emitting device 1 is configured to switch the irradiated light corresponding to the narrow-angle mode and the wide-angle mode, image capturing can be performed corresponding to image-capturing modes of the imaging device such as, for example, telephoto, close-up, etc., is possible. In the wide-angle mode, the illumination angle can be adjusted by controlling the light emission intensities of the light-emitting parts 20.

### Light-Emitting Part

As shown in FIG. 2, the plurality of light-emitting parts 20 are disposed at the upper surface of the substrate 10. Each light-emitting part 20 includes a semiconductor structure 21. The semiconductor structure 21 includes a first surface 21A, and a second surface 21B positioned at the side opposite to the first surface 21A in the third direction Z. For example, the first surface 21A is an upper surface, and the second surface 21B is a lower surface.

The semiconductor structure 21 includes a nitride semiconductor. In the specification, the term “nitride semiconductor” includes, for example, all compositions of semiconductors represented by the chemical formula InₓAl_{y}Ga_{1-x-y}N (0≤x≤1, 0≤y≤1, and x+y≤1) in which the composition ratios x and y are varied within respective ranges. Further, the term “nitride semiconductor” include nitride semiconductors that further contain Group V elements other than N (nitrogen) in the chemical formula above, and nitride semiconductors that contain various elements added to control various properties such as the conductivity type of the semiconductor, etc. The semiconductor structure 21 includes an active layer. The active layer is a light-emitting layer that emits light and has, for example, a MQW (Multiple Quantum well) structure that includes multiple barrier layers and multiple well layers. The light that is emitted by the active layer is, for example, visible light or ultraviolet light. For example, a plurality of light-emitting parts 20 are selected such that variation in the optical characteristics (the luminance, the chromaticity, etc.) is within a predetermined range, and are used in the light-emitting device 1. The light-emitting part 20 may further include a protective film protecting the semiconductor structure 21.

The plurality of light-emitting parts 20 may include light-emitting parts 20 having the same light emission peak wavelength, or may include light-emitting parts 20 having different light emission peak wavelengths. The “Light-emitting parts 20 that have the same light emission peak wavelength” may be light-emitting parts having light emission peak wavelengths within a range of +5 nm.

The light-emitting part 20 shown in FIG. 2 does not include an element substrate that has been used for growing the semiconductor structure 21. Accordingly, the light that is emitted by the active layer can be inhibited from being reflected at a lateral surface of the element substrate and returning to the semiconductor structure 21, and thus the light extraction efficiency can be increased. With the light-emitting part 20 that does not include an element substrate, spread of light from the light-emitting part 20 due to propagation of light emitted by the active layer inside the element substrate can be reduced, so that the illuminance of the light of each light-emitting part 20 at the irradiation surface can be improved. An upper surface 20A of the light-emitting part 20 may be the first surface 21A of the semiconductor structure 21; or, when a protective film on the first surface 21A covers the first surface 21A, the upper surface 20A of the light-emitting part 20 may be the upper surface of the protective film.

Each light-emitting part 20 further includes positive and negative electrode parts 22 disposed at the second surface 21B of the semiconductor structure 21. One of the positive and negative electrode parts 22 functions as an anode electrode, and the other functions as a cathode electrode. The positive and negative electrode parts 22 includes an anode electrode and a cathode electrode, and may include three or more electrode parts.

The first surface 21A of the semiconductor structure 21 may include a rough-surface portion. The arithmetic average roughness of the rough-surface portion of the first surface 21A is, for example, not less than 0.5 μm and not more than 10 μm. With the first surface 21A of the semiconductor structure 21 including the rough-surface portion, the light extraction efficiency from the first surface 21A of the semiconductor structure 21 can be increased.

### Substrate

The plurality of light-emitting parts 20 are arranged at the upper surface of the substrate 10 to be separated from each other in the first and second directions X and Y. The substrate 10 functions as a supporting member of the light-emitting parts 20. The thickness of the substrate 10 is greater than the thickness of the first resin part 30 and the thicknesses of the light-emitting parts 20 without the element substrate. By setting the thickness of the substrate 10 as described above, the mechanical strength can be increased, and damage or the like of the thin light-emitting part 20 and first resin part 30, when, e.g., operating the light-emitting device 1, can be reduced. Also, influence on the light-emitting part 20 and the first resin part 30 by, e.g., vibrations when removing the element substrate in a step of removing the element substrate described below can be reduced. The thickness of the substrate 10 is, for example, not less than 80 μm and not more than 500 μm, and favorably not less than 150 μm and not more than 300 μm. As a result, the light-emitting device 1 can be smaller while increasing the mechanical strength of the substrate 10. The thickness of the light-emitting part 20 is, for example, not less than 3 μm and not more than 30 μm, or not less than 5 μm and not more than 15 μm. The thickness of the first resin part 30 is greater than the thickness of the light-emitting part 20 by at least the thickness of a bonding member 80 and the like. The thickness of the first resin part 30 is, for example, not less than 8 μm and not more than 200 μm, or not less than 8 μm and not more than 100 μm.

The substrate 10 also functions as a wiring member that electrically connects the light-emitting parts 20 and an external circuit. The substrate 10 includes a plurality of positive and negative wiring parts 11 at the upper surface. Specifically, the substrate 10 includes an insulating base member 13, and a plurality of first wiring parts 11 disposed at an upper surface 13A of the insulating base member 13. Positive and negative first wiring parts 11 is disposed for one light-emitting part 20. One of the positive and negative first wiring parts 11 is electrically connected with one of the positive and negative electrode parts 22 of the light-emitting part 20, and the other of the positive and negative first wiring parts 11 is electrically connected with the other of the positive and negative electrode parts 22 of the light-emitting part 20. The positive and negative wiring parts 11 includes an anode-side wiring part and a cathode-side wiring part, and may include three or more wiring parts.

The insulating base member 13 includes a lower surface 13B positioned at a side opposite to the upper surface 13A in the third direction Z. The substrate 10 can further include a second wiring part 12 disposed at the lower surface 13B of the insulating base member 13. For example, the second wiring part 12 can be electrically connected with the first wiring part 11 via a conductive member extending through the insulating base member 13. The second wiring part 12 functions as an external connection terminal electrically connected with a mounting substrate to which the light-emitting device 1 is mounted. The substrate 10 is not limited to the two-layer wiring structure of the first and second wiring parts 11 and 12, and may have a multilayer wiring structure of three or more layers.

For example, aluminum nitride, aluminum oxide, or silicon nitride can be used as a material of the insulating base member 13. When aluminum nitride is used as the material of the insulating base member 13, the heat dissipation of the substrate 10 can be improved, and the heat generated due to the light emission of the light-emitting part 20 can be efficiently dissipated. When silicon nitride is used as the material of the insulating base member 13, the thickness of the substrate 10 can be reduced while maintaining the mechanical strength of the substrate 10.

### First Resin Part

The first resin part 30 holds the plurality of light-emitting parts 20. The first resin part 30 is disposed on the upper surface of the substrate 10, and is disposed between the second surface 21B of the semiconductor structure 21 and the upper surface of the substrate 10. The first resin part 30 is disposed between adjacent ones of light-emitting parts 20, and covers the lateral surfaces of the light-emitting parts 20. The first resin part 30 also covers outermost lateral surfaces of outermost light-emitting parts 20 of the plurality of light-emitting parts 20 in a plan view. A lateral surface of the light-emitting part 20 includes a lateral surface 21C of the semiconductor structure 21 and the lateral surface of the electrode part 22. The first resin part 30 is not disposed at the upper surface 20A of the light-emitting part 20, and the upper surface 20A of the light-emitting part 20 is exposed from the first resin part 30. The first resin part 30 is disposed between the positive and negative electrode parts 22 of each light-emitting part 20. The first resin part 30 is insulative, and prevents short-circuits between the positive and negative electrode parts 22.

The first resin part 30 includes a resin part as a base material, and a metal oxide included in the resin part. In the light-emitting device 1 shown in FIG. 2, the first resin part 30 includes a light-reflecting part 31 that is reflective to the light emitted by the light-emitting part 20, and a light-absorbing part 32 disposed on the light-reflecting part 31. The light-reflecting part 31 has a reflectance higher than the light-absorbing part 32, and the light-absorbing part 32 has an optical absorptance higher than the light-reflecting part 31. The light-absorbing part 32 is disposed at least between adjacent light-emitting parts 20. The reflectance of the light-reflecting part 31 is not less than 70%, not less than 80%, or not less than 90% for light of a light emission peak wavelength of 450 nm. The reflectance of the light-absorbing part 32 is not more than 50%, not more than 40%, or not more than 30% for light of a light emission peak wavelength of 450 nm. The optical absorptance of the light-reflecting part 31 is not more than 30%, not more than 20%, or not more than 10% for light of a light emission peak wavelength of 450 nm. The optical absorptance of the light-absorbing part 32 is not less than 50%, not less than 60%, or not less than 70% for light of a light emission peak wavelength of 450 nm. For example, the reflectance and the optical absorptance can be measured using a spectrophotometer.

In the light-emitting device 1 shown in FIG. 2, the upper surface of the light-absorbing part 32 forms an upper surface 30A of the first resin part 30 between adjacent light-emitting parts 20. For example, the light-absorbing part 32 is positioned higher than the active layer of the semiconductor structure 21 between adjacent light-emitting parts 20. With this structure, the light-absorbing part 32 can absorb a portion of the light emitted from the active layer of the semiconductor structure 21, and the light of the light-emitting part 20 that is emitted toward the adjacent light-emitting parts 20 can be reduced. For example, the light-absorbing part 32 is positioned at the first surface 21A side of the semiconductor structure 21 relative to a position at ½ of the thickness of the semiconductor structure 21. The thickness of the semiconductor structure 21 is, for example, not less than 2 μm and not more than 25 μm, or not less than 4 μm and not more than 15 μm. The thickness of the light-absorbing part 32 is, for example, not more than 2 μm.

Including the light-reflecting part 31 between the adjacent light-emitting parts 20 allows for inhibiting, when one light-emitting part 20 emits light while a light-emitting part 20 adjacent to the one light-emitting part 20 does not emit light, the light that is emitted by the one light-emitting part 20 from being irradiated toward the light-emitting parts 20 not emitting light. As a result, the light-emitting device 1 can have high contrast (the luminance ratio of the light-emitting region and the non-light-emitting region). Further, including the light-absorbing part 32 between adjacent light-emitting parts 20 allows for further improving the contrast of the light-emitting device 1.

With the light-absorbing part 32 positioned at a lateral side of the upper surface 20A of the light-emitting part 20, which is the light-emitting surface of the light-emitting part 20, multiple reflections at the interface between the first resin part 30 and the lateral surface of the light-emitting part 20 at the vicinity of the light-emitting surface of the light-emitting part 20 can be reduced compared to when the light-reflecting part 31 is positioned at the lateral side of the upper surface 20A. As a result, the interface between the light-emitting part 20 and the first resin part 30 can be inhibited from appearing as a bright line in a plan view of the light-emitting device 1.

A portion of the first resin part 30 is positioned outward of the plurality of light-emitting parts 20 in a plan view. The light-reflecting part 31 covers the outermost lateral surfaces of the outermost light-emitting parts 20 of the plurality of light-emitting parts 20 in a plan view. This structure allows for reducing the emission of light to the outside the region in which the plurality of light-emitting parts 20 are disposed (in the non-light-emitting region), and the light-emitting device 1 can have high contrast.

For example, the upper surface 20A of the light-emitting part 20 and the upper surface 30A of the first resin part 30 are coplanar at the upper surface of the first structure 101. In the light-emitting device 1 as described below, it is favorable to polish the upper surface of the first structure 101 after removing the element substrate. By performing the polishing, the upper surface 20A of the light-emitting part 20 and the upper surface 30A of the first resin part 30 can be coplanar, and cracks and the like of the semiconductor layer caused by the step of removing the element substrate can be removed. In another example, the upper surface 30A of the first resin part 30 may include a portion that is coplanar with the upper surface 20A of the light-emitting part 20, and a portion at a position different in the height direction than the upper surface 20A of the light-emitting part 20. For example, the upper surface 30A of the first resin part 30 may include, in a region adjacent to the upper surface 20A of the light-emitting part 20, a portion that is coplanar with the upper surface 20A of the light-emitting part 20, and the first resin part 30 may include a protrusion or recess in a region positioned outward of the plurality of light-emitting parts 20 in a plan view.

The first resin part 30 can include, for example, a resin base material and a metal oxide. For example, a thermosetting resin such as a silicone resin, a silicone-modified resin, an epoxy resin, an epoxy-modified resin, a phenol resin, etc., can be used as a material of the resin base material. Among these materials, a silicone resin or a modified resin of a silicone resin has excellent lightfastness and heat resistance, and is especially favorable. For example, titanium oxide can be used as the metal oxide. For example, the optical absorptance of titanium oxide may be changed by irradiation with laser light from the upper surface 30A side of the first resin part 30, thus forming the light-absorbing part 32. The optical absorptance of the light-absorbing part 32 including the titanium oxide after the change is greater than the optical absorptance of the light-reflecting part 31 including the titanium oxide before the change. The first resin part 30 does not necessarily include a metal oxide, or may include silicon oxide, etc., instead of a metal oxide. Alternatively, the light-absorbing part 32 can include a resin base material and a light-absorbing substance such as carbon black, etc.

The light-absorbing part 32 is, for example, a resin portion that is located in a portion irradiated with laser light when the laser light is emitted from the upper surface 30A side of the first resin part 30 and that contains a titanium oxide (hereinbelow referred to as an altered titanium oxide) in which an oxide component is deficient. The altered titanium oxide has a band-gap energy smaller than that of a titanium oxide before being irradiated with laser light. Further, the altered titanium oxide contained in the light-absorbing part 32 has a band-gap energy smaller than that of a titanium oxide contained in the light-reflecting part 31. The titanium oxide before being irradiated with laser light is, for example, a titanium oxide having a rutile crystal structure.

### Second Structure

The second structure 102 is disposed on the first structure 101. The second structure 102 includes a plurality of wavelength conversion members 40 and a second resin part 50. The plurality of wavelength conversion members 40 are collectively held by the second resin part 50.

### Wavelength Conversion Member

Each of the plurality of wavelength conversion members 40 is disposed on a respective one of the light-emitting parts 20. The wavelength conversion member 40 is configured to convert a wavelength of at least a portion of the light emitted by the light-emitting part 20. The light-emitting device 1 emits light in which the light emitted by the light-emitting part 20 and the light whose wavelength has been converted by the wavelength conversion member 40 are mixed.

The distance between two adjacent light-emitting parts 20 among the plurality of light-emitting parts 20 can be not less than 1 μm and not more than 15 μm. By setting the distance between two adjacent light-emitting parts 20 to be narrow as described above, a larger light-emitting part 20 can be used for the same planar area of the light-emitting device 1 and same number of the light-emitting parts 20. The light extraction of the light-emitting device 1 is improved thereby. The distance between two adjacent wavelength conversion members 40 of the plurality of wavelength conversion members 40 can be not less than 10 μm and not more than 80 μm, or not less than 15 μm and not more than 40 μm.

As shown in FIG. 1, the shape of the light-emitting part 20 and the shape of the wavelength conversion member 40 can be rectangular in a plan view. The length of the long side of the light-emitting part 20 is, for example, not less than 100 μm and not more than 2,000 μm, or not less than 200 μm and not more than 1,000 μm. The length of the long side of the wavelength conversion member 40 is, for example, not less than 150 μm and not more than 950 μm. When the shape of the light-emitting part 20 and the shape of the wavelength conversion member 40 are square, one side of the light-emitting part 20 or the wavelength conversion member 40 is regarded as the long side of the light-emitting part 20 or the wavelength conversion member 40 described above.

An outer edge 40E of the wavelength conversion member 40 is positioned inward of an outer edge 20E of the light-emitting part 20 in a plan view. With this structure, each light-emitting part 20 can emit light of a narrow angle with reduction in spread of light compared to when the outer edge 40E of the wavelength conversion member 40 coincides with or is positioned outward of the outer edge 20E of the light-emitting part 20 in a plan view. The wavelength conversion member 40 is disposed at a position at which the wavelength conversion member 40 does not overlap the light-absorbing part 32 in a plan view. With this structure, light that undergoes wavelength conversion or is reflected by the wavelength conversion substance or light-diffusing substance included in the wavelength conversion member 40 can be inhibited from returning to the light-emitting part 20 side and being partially absorbed by the light-absorbing part 32. Accordingly, the light extraction efficiency of the light-emitting device 1 can be increased. The outer edge 40E of the wavelength conversion member 40 may coincides with or may be positioned outward of the outer edge 20E of the light-emitting part 20 in a plan view.

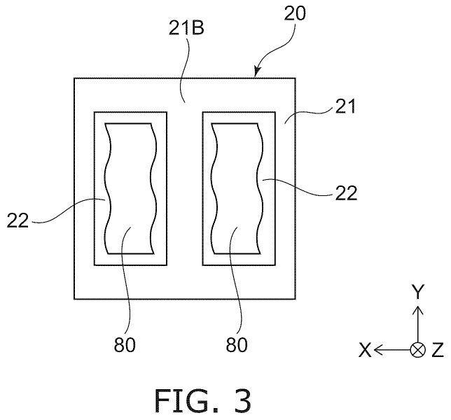

The light-emitting device 1 can further include bonding members 80, each bonding a respective one of the positive and negative electrode parts 22 of the light-emitting part 20 and a respective one of the positive and negative first wiring parts 11 of the substrate 10 corresponding thereto. The electrode part 22 and the first wiring part 11 are electrically connected via the bonding member 80. For example, a gold-tin alloy can be used as a material of the bonding member 80. When a gold-tin alloy is used as the material of the bonding member 80, the contact area between the electrode part 22 and the bonding member 80 can be greater than that when the electrode part 22 and the first wiring part 11 are bonded by a gold bump. Accordingly, the electrical resistance or the thermal resistance between the electrode part 22 and the first wiring part 11 can be reduced, and the bonding strength between the electrode part 22 and the first wiring part 11 can be increased. As shown in FIG. 3, the area of the bonding member 80 in contact with the electrode part 22 can be, for example, not less than 70% of the area of the electrode part 22 in a plan view. The bonding member 80 may be a known bonding member such as a gold bump, etc.

As shown in FIG. 2, the wavelength conversion member 40 can include a phosphor layer 41 disposed on the first surface 21A of the semiconductor structure 21, a light-diffusing layer 42 disposed on the phosphor layer 41, and a light-transmitting layer 43 disposed on the light-diffusing layer 42.

The phosphor layer 41 includes, for example, a resin base material and a wavelength conversion substance similar to those of the first resin part 30. For example, an yttrium-aluminum-garnet-based phosphor (e.g., (Y, Gd)₃(Al, Ga)₅O₁₂:Ce), a lutetium-aluminum-garnet-based phosphor (e.g., Lu₃(Al, Ga)₅O₁₂:Ce), a terbium-aluminum-garnet-based phosphor (e.g., Tb₃(Al, Ga)₅O₁₂:Ce), a CCA-based phosphor (e.g., Ca₁₀(PO₄)₆Cl₂:Eu), an SAE-based phosphor (e.g., Sr₄Al₁₄O₂₅:Eu), a chlorosilicate-based phosphor (e.g., Ca₈MgSi₄O₁₆Cl₂:Eu), a silicate-based phosphor (e.g., (Ba, Sr, Ca, Mg)₂SiO₄:Eu), an oxynitride-based phosphor such as a β-sialon-based phosphor (e.g., (Si, Al)₃(O, N)₄:Eu), an α-sialon-based phosphor (e.g., Ca(Si, Al)₁₂(O, N)₁₆:Eu), or the like, a nitride-based phosphor such as an LSN-based phosphor (e.g., (La, Y)₃Si₆N₁₁:Ce), a BSESN-based phosphor (e.g., (Ba, Sr)₂Si₅N₈:Eu), an SLA-based phosphor (e.g., SrLiAl₃N₄:Eu), a CASN-based phosphor (e.g., CaAlSiN₃:Eu), a SCASN-based phosphor (e.g., (Sr, Ca)AlSIN₃:Eu), or the like, a fluoride-based phosphor such as a KSF-based phosphor (e.g., K₂SiF₆:Mn), a KSAF-based phosphor (e.g., K₂(Si₁₋ₓAlₓ)F₆₋ₓ:Mn, where x satisfies 0<X<1), a MGF-based phosphor (e.g., 3.5MgO·0.5MgF₂·GeO₂:Mn), or the like, a quantum dot having a perovskite structure (e.g., (Cs, FA, MA) (Pb, Sn) (F, Cl, Br, I)₃, where FA and MA are respectively formamidinium and methylammonium), a Group II-VI quantum dot (e.g., CdSe), a Group III-V quantum dot (e.g., InP), a quantum dot having a chalcopyrite structure (e.g., (Ag, Cu) (In, Ga) (S, Se)₂), etc., can be used as the wavelength conversion substance.

The phosphor layer 41 may include one type of wavelength conversion substance, and may include multiple types of wavelength conversion substances.

The light-diffusing layer 42 diffuses the light emitted by the light-emitting part 20 and the light after the wavelength conversion by the phosphor layer 41. For example, the light-diffusing layer 42 can include a resin base material and a light-diffusing substance similar to those of the first resin part 30. For example, titanium oxide, silicon oxide, etc., can be used as the light-diffusing substance. With the light-diffusing layer 42, the body color of the wavelength conversion member 40 and the body color of the second resin part 50 can be close to each other when the light-emitting device 1 is viewed from the light-emitting surface side in an unlit state, the light-emitting device can have a good appearance in the unlit state. It is preferable that the concentration of the light-diffusing substance of the light-diffusing layer 42 is less than the concentration of the light-reflective substance of the second resin part 50. This can facilitate extraction of light from the wavelength conversion member 40.

For example, the light-transmitting layer 43 can include a resin base material similar to that of the first resin part 30. The light-transmitting layer 43 does not include a light-diffusing substance. For the light emitted by the light-emitting part 20 and the light that has undergone the wavelength conversion by the phosphor layer 41, the transmittance of the light-transmitting layer 43 is greater than the transmittance of the light-diffusing layer 42.

### Second Resin Part

The second resin part 50 is disposed between the plurality of wavelength conversion members 40. The second resin part 50 is configured to reflect the light emitted by the light-emitting part 20 and the light having undergone the wavelength conversion by the wavelength conversion member 40. For example, the second resin part 50 can have a configuration similar to that of the light-reflecting part 31 of the first resin part 30. The light-reflective substance of the second resin part 50 is not limited to a metal oxide and may be silicon oxide, etc.

With the second resin part 50 between the adjacent wavelength conversion members 40, when one light-emitting part 20 emits light and a light-emitting part 20 adjacent to the one light-emitting part 20 does not emit light, the light emitted from the one light-emitting part 20 can be inhibited from being incident on the wavelength conversion member 40 on the light-emitting part 20 not emitting light, so that emission of light from the wavelength conversion substance included in the wavelength conversion member 40 on the light-emitting part 20 not emitting light can be reduced. Accordingly, the light-emitting device 1 can have high contrast.

The second resin part 50 is disposed on the light-absorbing part 32. With this arrangement, when the body color of the light-absorbing part 32 is, for example, black or the like, the region between adjacent light-emitting parts 20 can be inhibited from appearing black in the state in which both of the adjacent light-emitting parts 20 emit light. Compared to the case in which the second resin part 50 is not included or is configured to transmit light, the light-absorbing part 32 is not visible in a plan view of the light-emitting device 1, so that the light-emitting device can have a good appearance when not emitting light. The light-emitting device having a good appearance refers to, for example, a light-emitting device that has a simple appearance having few colors. For example, when the light-emitting device 1 is used as a flash-light source of a portable communication terminal, the light-emitting device 1 may be visible from the outside of the housing. In such a case, if the light-emitting device 1 has a simple appearance, the degree of freedom in design of the portable communication terminal is increased without impairing the overall appearance of the portable communication terminal.

In the light-emitting device shown in FIG. 2, the second resin part 50 does not cover outer lateral surfaces of outermost wavelength conversion members 40 that form outermost lateral surfaces of the plurality of wavelength conversion members 40 in a plan view. The light-emitting device of the disclosure is not limited thereto; the second resin part 50 may cover the outer lateral surfaces of the outermost wavelength conversion members 40 that form the outermost lateral surfaces of the plurality of wavelength conversion members 40 in a plan view.

The light-emitting device 1 can further include a third resin part 60 covering at least each of the lateral surface of the first resin part 30 and a portion of the upper surface of the substrate 10. The third resin part 60 is disposed on an outer perimeter part 10C, at which the first resin part 30 and the light-emitting part 20 are not disposed, of the upper surface of the substrate 10 and covers the outermost lateral surfaces of the first resin part 30. The third resin part 60 is light-reflective to the light emitted by the light-emitting part 20 and the light after the wavelength conversion by the wavelength conversion member 40. The third resin part 60 can further reduce the emission of light outside the region in which the plurality of light-emitting parts 20 are disposed (the non-light-emitting region), and the light-emitting device 1 can have high contrast.

The third resin part 60 also can be positioned outside the plurality of wavelength conversion members 40 in a plan view. The third resin part 60 is disposed, outside the plurality of wavelength conversion members 40, on the first resin part 30 and on the outer perimeter part 10C of the upper surface of the substrate 10, and covers the outermost lateral surfaces of the plurality of wavelength conversion members 40. With this structure, the emission of light to the outside of the region in which the plurality of wavelength conversion members 40 are disposed (the non-light-emitting region) can be reduced, and the light-emitting device 1 can have high contrast. For example, the third resin part 60 can have a configuration similar to that of the second resin part 50. Accordingly, the body color of the second resin part 50 and the body color of the third resin part 60 can be close to each other in a plan view, and the light-emitting device can have a good appearance when not emitting light.

The light-emitting device 1 can further include a light-transmitting adhesive layer 70 disposed between the first structure 101 and the second structure 102. The adhesive layer 70 continuously covers the upper surfaces 20A of the light-emitting parts 20 and the upper surface of the light-absorbing part 32. The adhesive layer 70 bonds the light-emitting part 20 and the wavelength conversion member 40 together and bonds the first resin part 30 and the second resin part 50 together.

The adhesive layer 70 is transmissive to the light emitted by the light-emitting part 20 so that the light emitted by the light-emitting part 20 is incident on the wavelength conversion member 40. For example, a thermoplastic resin such as acrylic, polycarbonate, cyclic polyolefin, polyethylene terephthalate, polyester, or the like, a thermosetting resin such as epoxy, silicone, etc., can be used as a material of the adhesive layer 70. The thickness of the adhesive layer 70 is, for example, not less than 1 μm and not more than 15 μm, or not less than 5 μm and not more than 10 μm.

The adhesive layer 70 can also cover the upper surface of the first resin part 30 positioned outward of the plurality of light-emitting parts 20 in a plan view. The light-absorbing part 32 may also be disposed below the adhesive layer 70 covering the upper surface of the first resin part 30 positioned outward of the plurality of light-emitting parts 20. In other words, the adhesive layer 70 may be disposed on the light-absorbing part 32. With this structure, the light that is emitted by the light-emitting part 20 can be absorbed by the light-absorbing part 32 in a region outside the plurality of light-emitting parts 20. Furthermore, the light that propagates through the light-transmitting adhesive layer 70 can be absorbed by the light-absorbing part 32. Accordingly, the light that is emitted in the region outside the plurality of light-emitting parts 20 can be reduced, and the light-emitting device 1 can have high contrast.

When the third resin part 60 described above is included, the adhesive layer 70 that is positioned outward of the plurality of light-emitting parts 20 can bond the third resin part 60 and the first resin part 30 together, and can bond the third resin part 60 and the outer perimeter part 10C of the upper surface of the substrate 10 together.

The first resin part 30 is not located at the outer perimeter part 10C of the upper surface of the substrate 10, so that the adhesive layer 70 can be disposed to be continuous and bent on the outer perimeter part 10C of the upper surface of the substrate 10, the lateral surfaces of the first structure 101 (the outermost lateral surfaces of the first resin part 30), and the upper surface of the first structure 101 in a cross-sectional view. As used herein, the term “cross section” refers to, for example, a cross section cut along a plane that passes through the center of the light-emitting device 1 and extends in one of the first direction X or the second direction Y in which a plurality of light-emitting parts 20 are arrayed. With the adhesive layer 70 bent along the stepped portion between the outer perimeter part 10C of the upper surface of the substrate 10 and the upper surface 30A of the first resin part 30, light that propagates through the light-transmitting adhesive layer 70 is less easily emitted outside the light-emitting device 1 from an end portion 70E of the adhesive layer 70.

In the light-emitting device 1, the lower surface of the wavelength conversion member 40 and the first surface 21A of the semiconductor structure 21 may be directly bonded together without using the adhesive layer 70. For example, as described below, a softenable member is used as a layer positioned at the lower layer of the wavelength conversion member 40. With such a structure, the first structure 101 and the second structure 102 may be bonded by softening this layer and then curing when disposing the second structure 102 on the first structure 101.

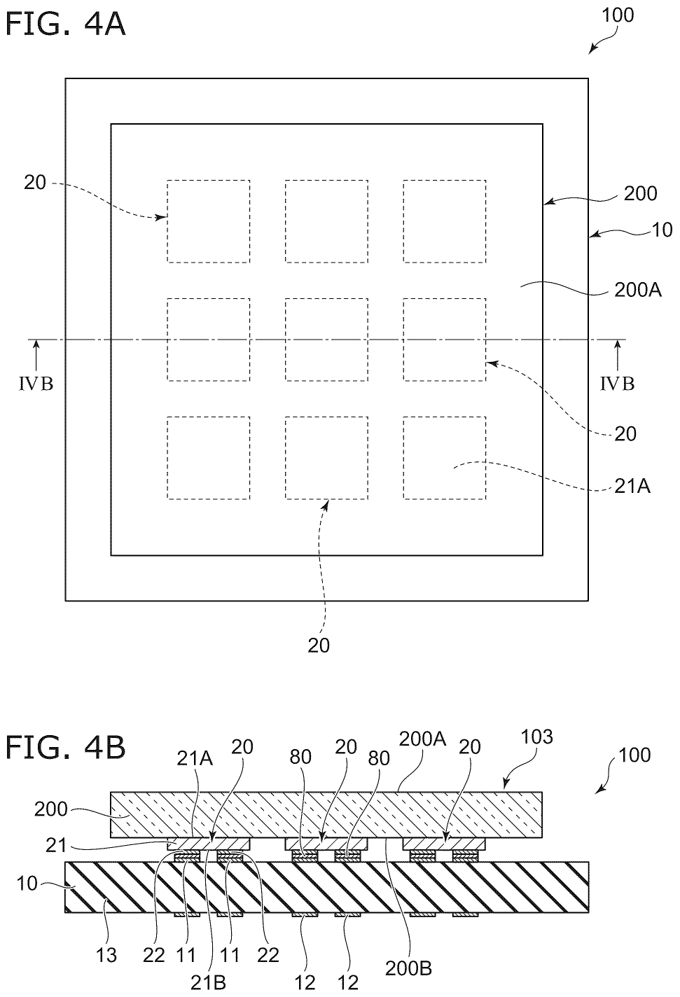

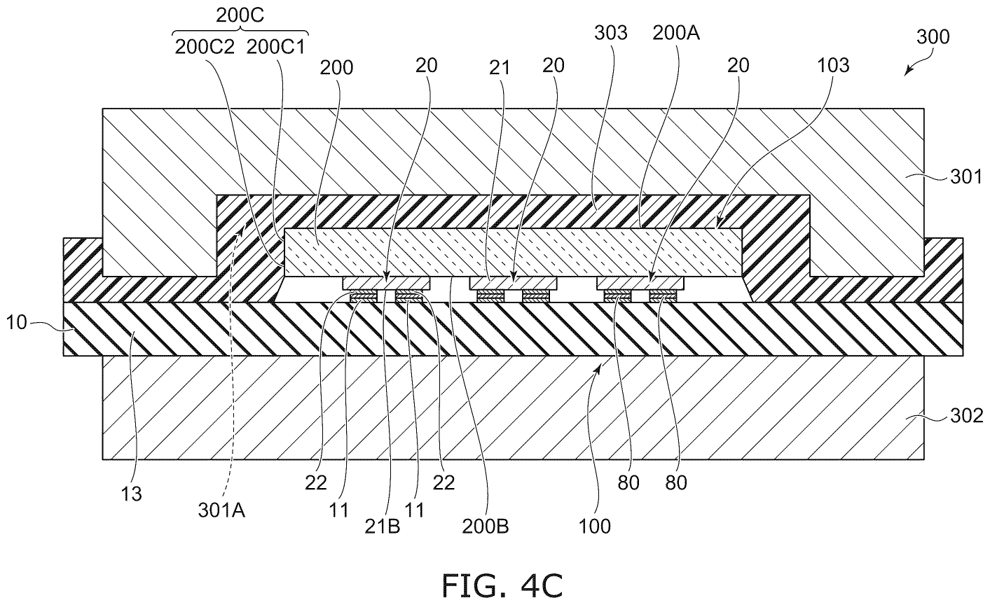

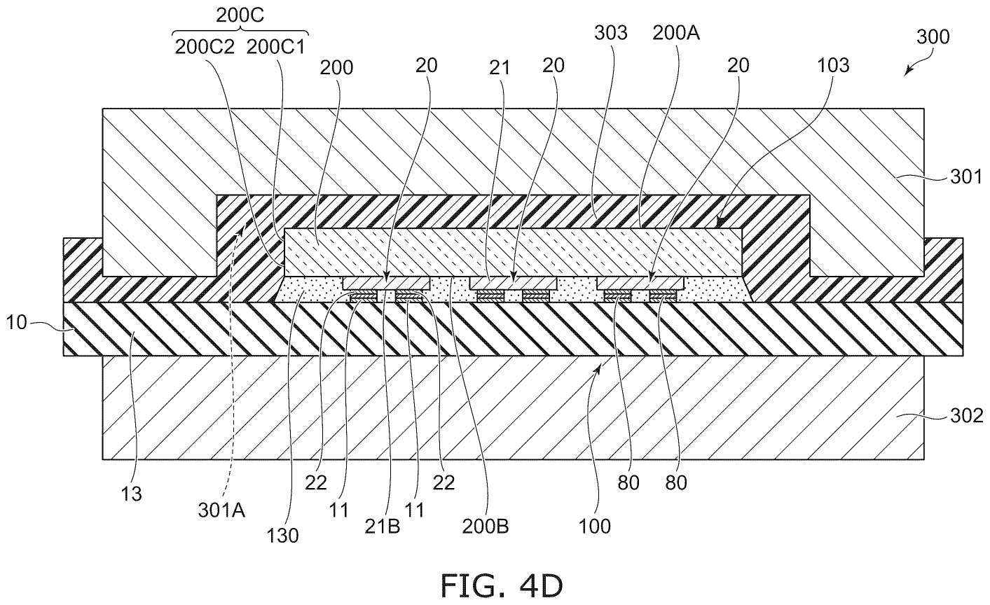

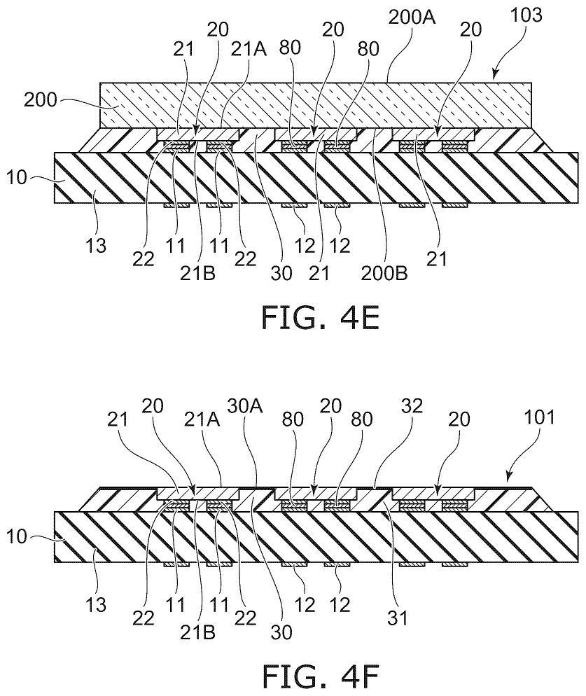

A method for manufacturing the light-emitting device according to the first embodiment will now be described with reference to FIGS. 4A to 6D.

The method for manufacturing the light-emitting device according to the first embodiment includes a step of providing the structure, a step of providing a mold, a step of disposing the first resin part, and a step of removing the element substrate from the light source part.

### Step of Providing Structure

As shown in FIGS. 4A and 4B, a structure 100 includes the substrate 10, and a light source part 103 disposed on the substrate 10. As described above, the substrate 10 includes a plurality of positive and negative first wiring parts 11 at the upper surface thereof. The light source part 103 includes an element substrate 200 and the plurality of light-emitting parts 20. The plurality of light-emitting parts 20 are arranged to be separated from each other in the first and second directions X and Y on the element substrate 200. As described above, each light-emitting part 20 includes the semiconductor structure 21, and the positive and negative electrode parts 22 disposed at the second surface 21B of the semiconductor structure 21. For example, the semiconductor structure 21 is formed on the element substrate 200 by MOCVD (metal organic chemical vapor deposition). After growing a semiconductor film on the element substrate 200, the semiconductor film is separated into the plurality of semiconductor structures 21 on the element substrate 200 by, for example, an etching technique such as RIE (Reactive Ion Etching), etc. The first surface 21A of the semiconductor structure 21 faces the element substrate 200. For example, each of the positive and negative electrode parts 22 is electrically connected with a corresponding one of the positive and negative first wiring parts 11 of the substrate 10 via a corresponding one of the bonding members 80 described above.

### Step of Providing Mold

As shown in FIG. 4C, a mold 300 includes an upper mold 301 and a lower mold 302. The upper mold 301 has a recess 301A. In FIGS. 4C and 4D, the second wiring part 12 at the lower surface of the substrate 10 of the structure 100 disposed in the mold 300 is not illustrated.

### Step of Disposing First Resin Part

The structure 100 is disposed between the upper mold 301 and the lower mold 302. With the lower surface of the substrate 10 facing the upper surface of the lower mold 302, the structure 100 is supported on the lower mold 302. The light source part 103 is disposed in the recess 301A of the upper mold 301 with an upper surface 200A of the element substrate 200 facing upward.

Then, the upper surface 200A of the element substrate 200 is covered with a covering member 303. In the example shown in FIG. 4C, the covering member 303 is disposed at the inner wall surface of the recess 301A, and then the covering member 303 covers at least the upper surface 200A of the element substrate 200. A portion of the covering member 303 extends toward outside the recess 301A and is held between the lower end portion of the upper mold 301 and the upper surface of the lower mold 302. At least the upper portion of the element substrate 200 is embedded in the covering member 303. Specifically, the covering member 303 may cover an upper portion 200C1 of a lateral surface 200C of the element substrate 200 positioned at the upper surface 200A side, in addition to the upper surface 200A of the element substrate 200. The covering member 303 also may cover a lower portion 200C2 of the lateral surface 200C of the element substrate 200 positioned at a lower surface 200B side. The lower surface 200B of the element substrate 200 and the second surface 21B of the semiconductor structure 21 are not covered with the covering member 303, and are exposed in the space inside the mold 300. The covering member 303 is, for example, a resin film made of a fluorine material. The thickness of the covering member 303 is, for example, not less than 100 μm and not more than 300 μm. When the covering member 303 is a resin film, the unevenness conformity of the covering member 303 is improved by using a resin film that is thicker than a conventional resin film (e.g., a mold release resin film used in molding) as the covering member 303. Accordingly, a resin material 130 can be inhibited from flowing into a space between the upper surface 200A of the element substrate 200 and the covering member 303.

As shown in FIG. 4D, the fluidic resin material 130 is supplied to the mold 300 in a state in which at least the upper surface 200A of the element substrate 200 is covered with the covering member 303. For example, a liquid resin material 130 is supplied to the mold 300. Subsequently, for example, the resin material 130 is cured by heating. After curing the resin material 130, the upper mold 301 is moved upward, and the covering member 303 is removed. As a result, as shown in FIG. 4E, the first resin part 30 formed of the cured resin material 130 described above is disposed at least between each of the second surfaces 21B of the semiconductor structures 21 and the upper surface of the substrate 10. The first resin part 30 may also be disposed between the lower surface 200B of the element substrate 200 and the upper surface of the substrate 10. The first resin part 30 that is disposed between the lower surface 200B of the element substrate 200 and the upper surface of the substrate 10 can cover the lateral surface of the light-emitting part 20.

For example, the first resin part 30 is formed by transfer molding and compression molding. For example, when the first resin part 30 is formed by compression molding, the substrate 10 is disposed on the upper surface of the lower mold, and then the fluidic resin material 130 is disposed on the upper surface of the substrate 10. Subsequently, the upper mold is closed, and the uncured resin material 130 is molded while compressing.

Step of removing element substrate from light source part After disposing the first resin part 30, the element substrate 200 is removed from the light source part 103. As shown in FIG. 4F, in the first structure 101 in which the element substrate 200 has been removed, the first surface 21A of the semiconductor structure 21 and the upper surface 30A of the first resin part 30 are exposed.

In the step of providing the structure 100 described above, for example, the element substrate 200 is a sapphire substrate, and the semiconductor structure 21 includes gallium nitride (GaN). In such a case, in the step of removing the element substrate 200 from the light source part 103, for example, the element substrate 200 can be removed by laser lift-off.

In laser lift-off, laser light is irradiated from the upper surface 200A side of the element substrate 200 toward the first surface 21A of the semiconductor structure 21 (the interface between the lower surface 200B of the element substrate 200 and the first surface 21A of the semiconductor structure 21). The laser light has a wavelength that allows the element substrate 200 to transmit the laser light and is in the region within which the semiconductor structure 21 absorbs the laser light. The laser light is, for example, light having a light emission peak wavelength of not less than 190 nm and not more than 380 nm. Gallium nitride is thermally decomposed when it absorbs the energy of the laser light. The irradiation of the laser light decomposes the gallium nitride at the first surface 21A into nitrogen and gallium, and causes the element substrate 200 to detach from the semiconductor structure 21. At this time, the gas (nitrogen gas) generated by the decomposition can cause the element substrate 200 to detach from a portion of the first resin part 30.

In the step of disposing the first resin part 30 described with reference to FIG. 4D, the upper surface 200A of the element substrate 200 is covered with the covering member 303, so that the first resin part 30 is not disposed on the upper surface 200A of the element substrate 200. Even if the resin material 130 flows into a region between the covering member 303 and the upper surface 200A of the element substrate 200, the amount of the first resin part 30 disposed at the upper surface 200A of the element substrate 200 can be less than when the covering member 303 is not used. With a configuration in which the first resin part 30 is reduced in amount on or is not located on the upper surface 200A of the element substrate 200, the laser light emitted in the laser lift-off described above can be inhibited from being absorbed or scattered by the first resin part 30 on the upper surface 200A of the element substrate 200. As a result, uneven irradiation of the laser light can be reduced, and the element substrate 200 can be easily removed from the light source part 103.

When the resin material 130 flows into a region between the covering member 303 and the upper surface 200A of the element substrate 200, it is favorable to include a step of removing a portion of the first resin part 30, the portion being located on the upper surface 200A of the element substrate 200. For example, a portion of the first resin part 30 that is disposed on the upper surface 200A of the element substrate 200 can be removed by wet blasting. In the wet blasting, a solution containing an abrasive is sprayed toward the upper surface 200A of the element substrate 200, and thus the portion of the first resin part 30 located on the upper surface 200A of the element substrate 200 can be removed by the impact force. When the amount of the portion of the first resin part 30 located on the upper surface 200A of the element substrate 200 is large, the removal efficiency of the portion of the first resin part 30 can be increased by increasing the spraying force of the solution containing the abrasive. However, if the spraying force of the solution containing the abrasive is increased, the upper surface 200A of the element substrate 200 is more likely to be damaged, so that the laser light emitted in the laser lift-off described above is more likely to be scattered or reflected by the upper surface 200A of the element substrate 200. As a result, there are cases where an undecomposed portion of the semiconductor layer remains at the interface between the lower surface 200B of the element substrate 200 and the first surface 21A of the semiconductor structure 21. When the element substrate 200 is removed in this state, stress may be exerted to the remaining undecomposed portion of the semiconductor layer, which may cause chipping of the semiconductor layer.

According to the present embodiment, the upper surface 200A of the element substrate 200 is covered with the covering member 303 in the step of disposing the first resin part 30. This allows for reducing the amount of the resin material 130 even when the resin material 130 is located at the upper surface 200A of the element substrate 200. Therefore, the spraying force of the solution including the abrasive can be reduced, which can prevent scratches of the upper surface 200A of the element substrate 200, so that the laser light emitted in laser lift-off can be inhibited from being scattered or reflected by the upper surface 200A of the element substrate 200. As a result, unevenness in irradiation of the laser light can be reduced, so that the element substrate 200 can be easily removed from the light source part 103.

A silicone resin or an epoxy resin can be used as a material of the first resin part 30 appropriate for removing the element substrate 200 by laser lift-off. After irradiating the laser light, for example, the element substrate 200 can be removed from the light-emitting part 20 and the first resin part 30 by suctioning with a nozzle and lifting upward. At this time, the first resin part 30 also may be lifted upward by being pulled by the element substrate 200. As a result, the force applied to lift the first resin part 30 may be exerted to the outer perimeter part of the semiconductor structure 21, which may cause chipping of the outer perimeter part of the semiconductor structure 21. Because a silicone resin has a weaker bonding force with the element substrate 200 than an epoxy resin, when a silicone resin is used as the material of the first resin part 30, compared to when an epoxy resin is used, the element substrate 200 is not easily pulled, and chipping of the outer perimeter part of the semiconductor structure 21 does not occur easily. Favorably, for example, a silicone-modified resin such as a SMC resin can be used as the silicone resin. A silicone-modified resin such as a SMC resin or the like has a higher hardness than an epoxy resin. Therefore, when a silicone-modified resin such as a SMC resin or the like is used as the material of the first resin part 30, compared to when an epoxy resin is used, the first resin part 30 is more resistant to impact in the removal of the element substrate 200 and thus cracks or the like is less likely to occur in the first resin part 30.

The laser light is irradiated also on the upper surface 30A of the first resin part 30 in the laser lift-off. As a result, the light-absorbing part 32 described above can be formed at the upper surface 30A side of the first resin part 30. The metal oxide (e.g., titanium oxide) contained in the first resin part 30 absorbs the energy of the laser light and alters, so that the light-absorbing part 32 that has a high light absorbance is formed at the upper surface 30A side of the first resin part 30.

Thus, the first structure 101 can be obtained. In the specification, the structure that has been subjected to a polishing step and/or roughening step described below, which are performed after the step of removing the element substrate from the light source part, also may be described as the first structure 101. The structure 100 and the first structure 101 described above may be provided by transfer including purchasing, etc.

### Step of Removing a Portion of Semiconductor Structure at First Surface Side and a Portion of First Resin Part

The method for manufacturing the light-emitting device according to the first embodiment can further include, after removing the element substrate 200, a step of removing another portion of the semiconductor structure 21 at the first surface 21A side and a portion of the first resin part 30.

Cracks may be generated in the first surface 21A of the semiconductor structure 21 when removing the element substrate 200. When cracks are generated in the first surface 21A of the semiconductor structure 21, the light emission characteristics of the light-emitting part 20 may degrade, and the cracks may extend when operating the light-emitting device 1, causing non-lighting of the light-emitting part 20. It is therefore favorable to remove the cracks of the first surface 21A of the semiconductor structure 21 by removing a portion of the semiconductor structure 21 at the first surface 21A side (a portion in the thickness direction) after the element substrate 200 is removed.

For example, while dropping a working fluid onto the first surface 21A of the semiconductor structure 21 and the upper surface 30A of the first resin part 30, a rotating disk-shaped polishing member is brought into contact with the first surface 21A of the semiconductor structure 21 and the upper surface 30A of the first resin part 30, and the portion of the semiconductor structure 21 at the first surface 21A side is polished to be removed. At this time, a portion of the first resin part 30 at the upper surface 30A side is also polished to be removed. The polishing member includes a soft grindstone. This allows for reducing, compared to when a polishing member including a hard grindstone is used, roughening and chipping of the first surface 21A of the semiconductor structure 21.

The first surface 21A of the semiconductor structure 21 and the upper surface 30A of the first resin part 30 are simultaneously polished using the disk-shaped polishing member. The polishing amount is, for example, a thickness of not more than 30% of the thickness of the semiconductor structure 21 before polishing. The first surface 21A of the semiconductor structure 21 and the upper surface 30A of the first resin part 30 after polishing are coplanar with each other.

Instead of performing the polishing described above, for example, when the first resin part 30 includes a protrusion at the upper surface 30A side, the protrusion may be removed by blade or laser processing.

### Surface Roughening of First Surface of Semiconductor Structure

The method for manufacturing the light-emitting device according to the first embodiment can perform surface roughening of the first surface 21A of the semiconductor structure 21 after the polishing described above. This can increase the efficiency of light extraction from the first surface 21A of the semiconductor structure 21. The arithmetic average roughness of the first surface 21A before the surface roughening is, for example, not less than 0 μm but less than 0.5 μm, and the arithmetic average roughness of the first surface 21A after the surface roughening is, for example, not less than 0.5 μm and not more than 10 μm. For example, the surface roughening can be performed by RIE using a gas containing chlorine, wet etching using an alkaline solution such as TMAH (tetramethylammonium hydroxide), etc.

### Step of Disposing Second Structure

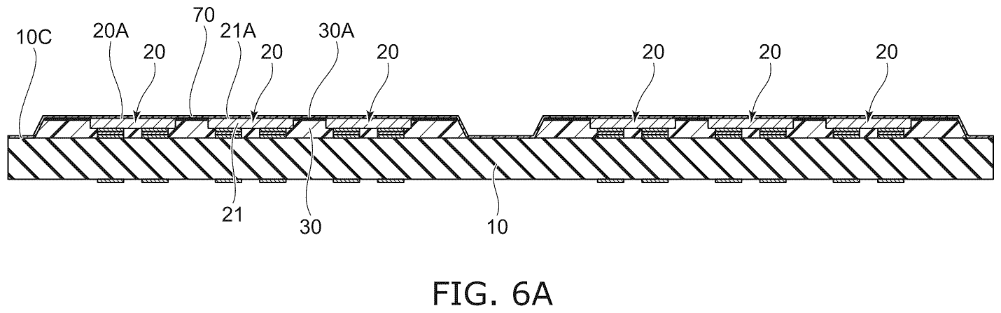

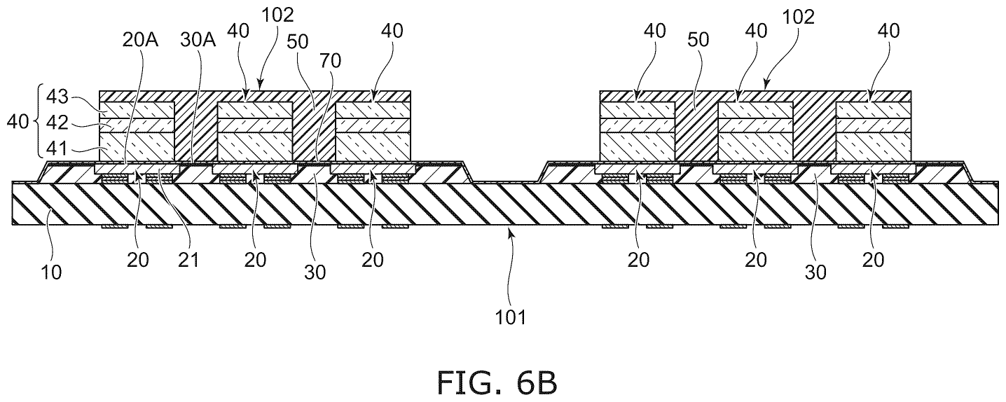

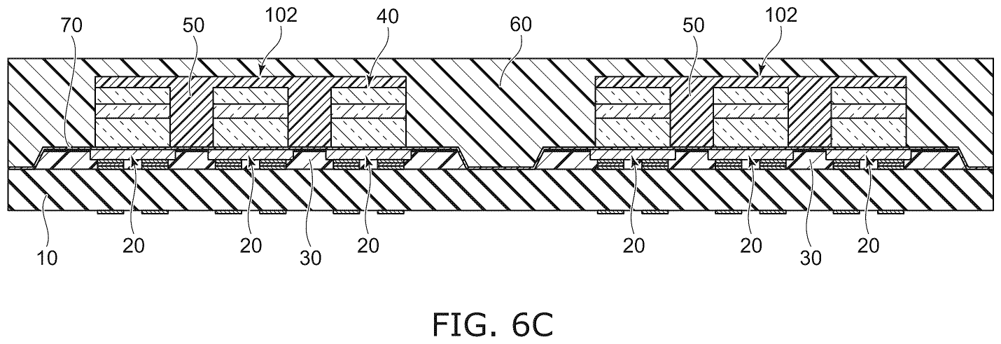

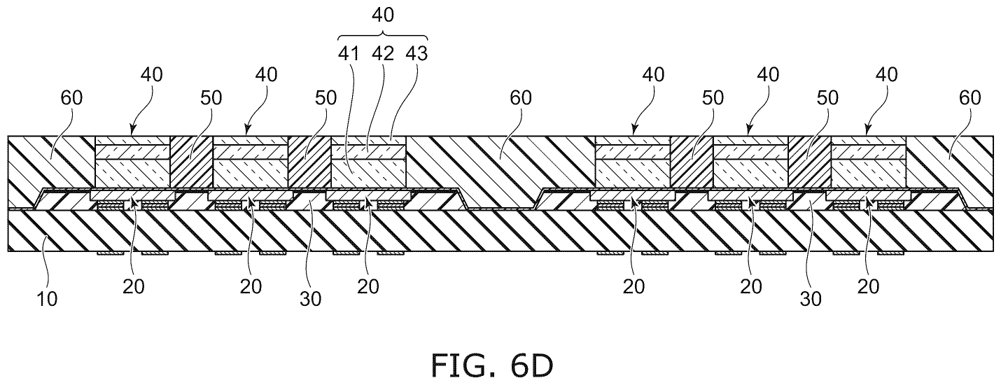

As shown in FIG. 6B, the method for manufacturing the light-emitting device according to the first embodiment further includes a step of disposing the second structure 102 on the first surface 21A of the semiconductor structure 21 of the first structure 101 obtained after the element substrate 200 is removed. The second structure 102 includes the plurality of wavelength conversion members 40, and the second resin part 50 that is disposed between the plurality of wavelength conversion members 40 and holds the plurality of wavelength conversion members 40. As described above, the wavelength conversion member 40 includes the phosphor layer 41 disposed on the first surface 21A of the semiconductor structure 21, the light-diffusing layer 42 disposed on the phosphor layer 41, and the light-transmitting layer 43 disposed on the light-diffusing layer 42.

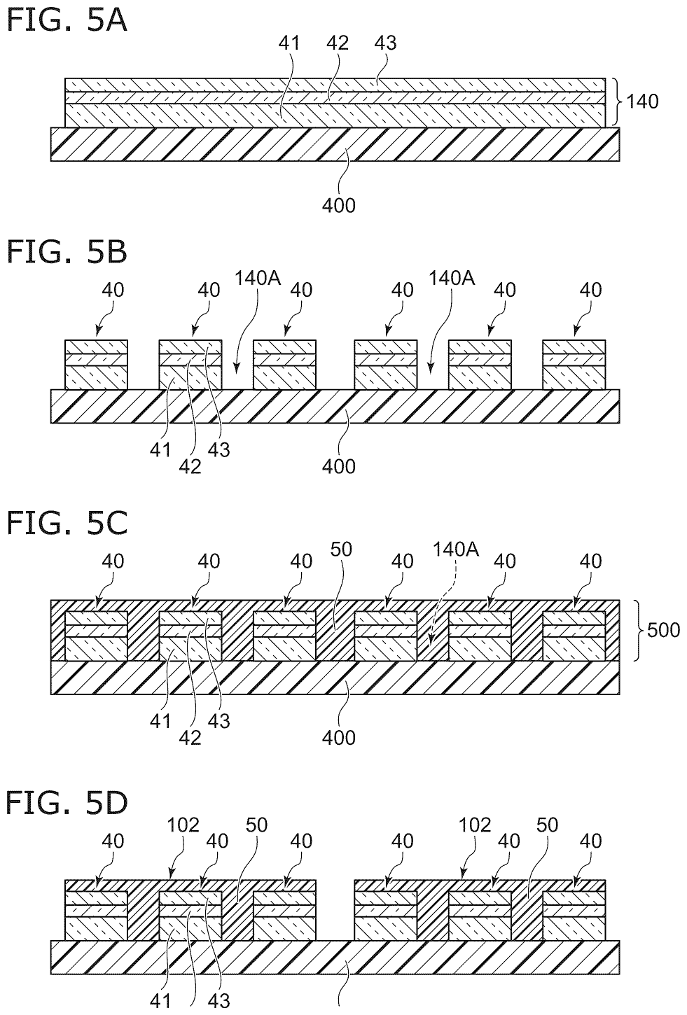

The second structure 102 can be provided by transfer including purchasing, etc. Alternatively, providing the second structure 102 can include steps shown in FIGS. 5A to 5D.

In the step shown in FIG. 5A, a wavelength conversion sheet 140 is disposed on a support part 400. The wavelength conversion sheet 140 includes the phosphor layer 41 disposed on the support part 400, the light-diffusing layer 42 disposed on the phosphor layer 41, and the light-transmitting layer 43 disposed on the light-diffusing layer 42.

In the step shown in FIG. 5B, the wavelength conversion sheet 140 is separated into the plurality of wavelength conversion members 40. For example, a groove 140A is formed in the wavelength conversion sheet 140 by blade or laser processing, and the wavelength conversion sheet 140 is separated into the plurality of wavelength conversion members 40. The groove 140A extends through the phosphor layer 41, the light-diffusing layer 42, and the light-transmitting layer 43 and reaches the upper surface of the support part 400.

In the step shown in FIG. 5C, the second resin part 50 is disposed on the support part 400 to cover the plurality of wavelength conversion members 40. The second resin part 50 is formed by compression molding using a die, etc. The second resin part 50 is in contact with the support part 400 and is also disposed in the groove 140A. The second resin part 50 shown in FIG. 5C also covers the upper surface of the light-transmitting layer 43.

Then, in the step shown in FIG. 5D, a structure 500 on the support part 400 is separated into the plurality of second structure bodies 102 by, for example, cutting the second resin part 50 by blade or laser processing. In the second structure 102, the second resin part 50 is disposed between the adjacent wavelength conversion members 40 and covers the upper surface of the light-transmitting layer 43, which is the upper surface of the wavelength conversion member 40.

In the step of forming the groove 140A, there are cases where the groove 140A reaches a portion of the support part 400 and forms a recess in the upper surface of the support part 400. In such a case, a portion of the second resin part 50 may be located inside the recess in the step of disposing the second resin part 50. Therefore, the support part 400 may be removed from the structure 500 shown in FIG. 5C or the second structure 102 shown in FIG. 5D, and the portion of the second resin part 50 located inside the recess at the side from which the support part 400 has been removed (the phosphor layer 41 side) may be removed by polishing, etc. This allows the second structure 102 to be inhibited from being disposed in a tilted orientation when the second structure 102 is disposed on the first structure 101 such that the phosphor layer 41 side of the second structure 102 faces the first structure 101.

As a variation, a support substrate of glass or the like may be disposed at the upper surface side (the light-transmitting layer 43 side) of the second structure 102 when disposing the second structure 102 on the first structure 101. For example, the support substrate of glass or the like is disposed on the upper surface of the second structure 102 obtained in FIG. 5D. When the second structure 102 is formed by compression molding, etc., there are cases where warpage occurs due to difference between the linear expansion coefficient the wavelength conversion member 40 and that of the second resin part 50. Therefore, disposing the support substrate of glass or the like at the upper surface side of the second structure 102 allows the second structure 102 to be disposed on the first structure 101 in a state in which warpage is reduced.

### Step of Disposing Third Resin Part on Substrate

As shown in FIG. 6C, the method for manufacturing the light-emitting device according to the first embodiment can further include, after the second structure 102 is disposed, a step of disposing the third resin part 60 on the substrate 10 so as to cover the first structure 101 and the second structure 102. The third resin part 60 shown in FIG. 6C also covers the upper surface of the second resin part 50 covering the upper surface of the light-transmitting layer 43.

### Step of Simultaneously Removing Third Resin Part, Second Resin Part Covering Upper Surface of Light-Transmitting Layer, and a Portion of Light-Transmitting Layer at Upper Surface Side

The method for manufacturing the light-emitting device according to the first embodiment can further include a step of simultaneously removing a portion of the third resin part 60, a portion of the second resin part 50 covering the upper surface of the light-transmitting layer 43, and a portion of the light-transmitting layer 43 at the upper surface side. The term “simultaneously removing” as used herein refers to removing the portion of the third resin part 60, the portion of the second resin part 50 covering the upper surface of the light-transmitting layer 43, and the portion of the light-transmitting layer 43 at the upper surface side are removed during a series of operations between the removal start and the removal end. For example, the portion of the third resin part 60, the portion of the second resin part 50 covering the upper surface of the light-transmitting layer 43, and the portion of the light-transmitting layer 43 at the upper surface side are removed from the upper surface side of the third resin part 60 are simultaneously removed using a polishing device or the like. By this step as shown in FIG. 6D, the upper surface of the light-transmitting layer 43 is not covered with the second and third resin parts 50 and 60. The upper surface of the light-transmitting layer 43, the upper surface of the second resin part 50, and the upper surface of the third resin part 60 are coplanar.

By simultaneously removing the portion of the second resin part 50 and the portion of the third resin part 60 when exposing the upper surface of the light-transmitting layer 43, the number of steps can be fewer than when the resin parts are removed separately. Also, the thickness of the light-transmitting layer 43 is reduced by removing the portion of the light-transmitting layer 43 at the upper surface side. In the step of removing the second resin part 50 and the third resin part 60, the light-transmitting layer 43 functions as a layer that prevents removal of the light-diffusing layer 42. Preventing removal of the light-diffusing layer 42 allows for reducing variation in the thickness of the light-diffusing layer 42 can be reduced. As a result, unevenness in the light-diffusing function among the light-emitting parts 20 can be reduced. Further, variation in color among the light-emitting parts 20 in a plan view when not emitting light can be reduced, and the light-emitting device can have a good appearance when not emitting light.

Subsequently, by using, for example, a blade, the third resin part 60 and the substrate 10 are cut in regions in which the first resin part 30 is not located, and thus are singulated into the light-emitting device 1 shown in FIG. 2.

In the step of disposing the second structure 102 shown in FIG. 6B, the second structure 102 can be disposed on the first surface 21A of the semiconductor structure 21 and on the first resin part 30 via the adhesive layer 70.

For example, as shown in FIG. 6A, the liquid adhesive layer 70 is supplied by spraying to the upper surface of the substrate 10, the lateral surfaces of the first resin part 30, the upper surface of the first resin part 30, and the first surface 21A of the semiconductor structure 21, and then cured. The adhesive layer 70 after curing is continuous and bent on the upper surface of the substrate 10, the lateral surface of the first resin part 30, the upper surface of the first resin part 30, and the first surface 21A of the semiconductor structure 21. As described above, the adhesive layer 70 is light-transmissive. With the adhesive layer 70 having a shape bent along the stepped portion between the upper surface of the substrate 10 and the upper surface of the first resin part 30, the light that propagates through the light-transmitting adhesive layer 70 is not easily emitted outside the light-emitting device from the end portion of the adhesive layer 70.

According to the method for manufacturing the light-emitting device according to the disclosure, the second structure 102 may be directly bonded on the first structure 101 without using the adhesive layer 70. In one example, a softenable member is used as a layer positioned at the lower layer of the wavelength conversion member 40. Accordingly, the first structure 101 and the second structure 102 may be bonded by softening this layer and then curing when disposing the second structure 102 on the first structure 101. For example, the phosphor layer 41 in the B-stage state may be disposed at the lower layer of the wavelength conversion member 40 when providing the second structure 102. After the wavelength conversion member 40 is disposed on the semiconductor structure 21, the phosphor layer 41 is cured to the C-stage state by heating.

According to the method for manufacturing the light-emitting device according to the first embodiment, the Shore hardness of the first resin part 30 after curing is preferably not less than HSD 70. The difference between the linear expansion coefficient of the semiconductor structure 21 and the linear expansion coefficient of the first resin part 30 after curing is preferably not more than 30 ppm. By using the first resin part 30 having the Shore hardness described above, the first resin part 30 can be resistant to impact when detaching the element substrate 200, and cracks or the like is less likely to generate in the first resin part 30. Further, reduction in the difference between the linear expansion coefficient of the first resin part 30 and the linear expansion coefficient of the semiconductor structure 21 facilitates deformation of the first resin part 30 following the expansion or contraction of the semiconductor structure 21 when the semiconductor structure 21 is heated by the laser light in the step of removing the element substrate 200. This allows for inhibiting generation of cracks or the like in the first resin part 30.

### Second Embodiment

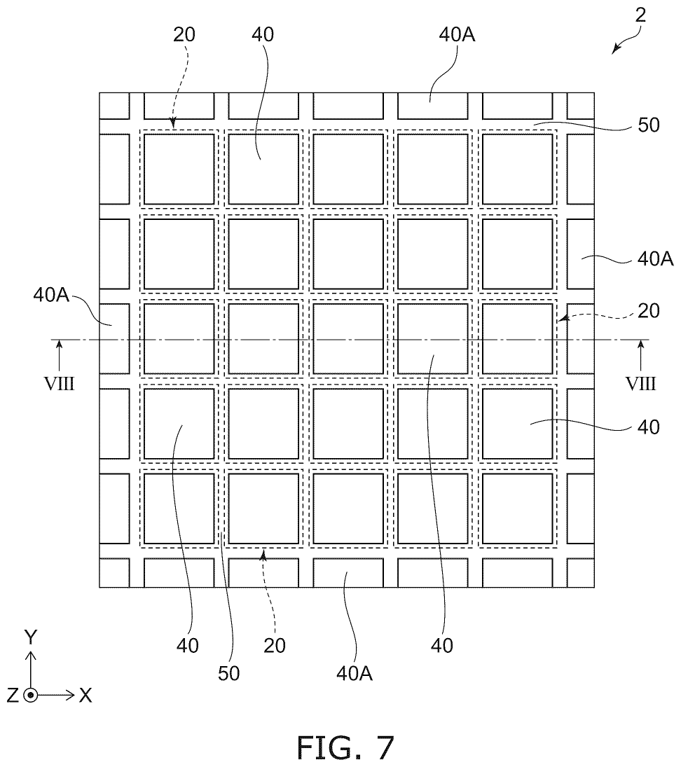

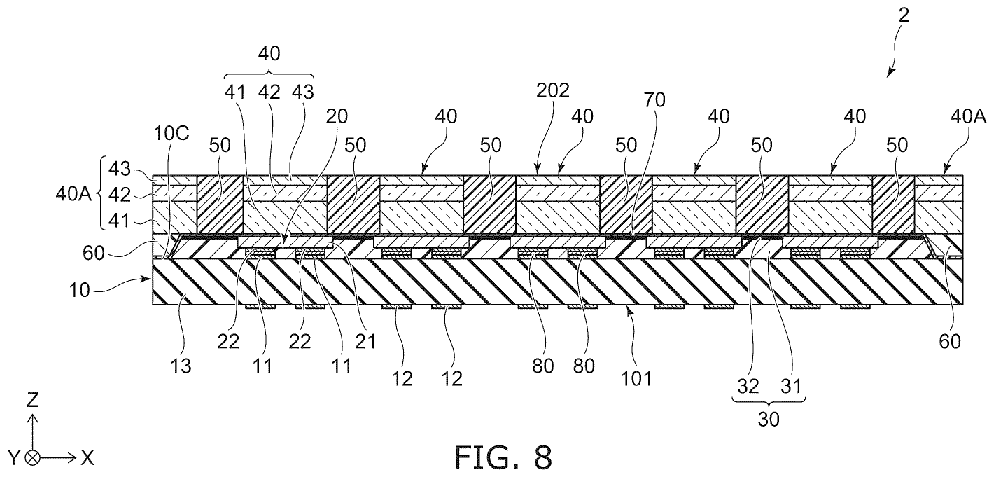

A light-emitting device 2 according to a second embodiment will now be described with reference to FIGS. 7 and 8.

As shown in FIG. 7, the light-emitting device 2 according to the second embodiment includes, for example, twenty-five light-emitting parts 20. 5×5 light-emitting parts 20 are arranged in the first and second directions X and Y.

Mainly, the configuration of a second structure 202 of the light-emitting device 2 is different from the second structure 102 of the light-emitting device 1 of the first embodiment.

The second structure 202 includes an outer perimeter wavelength conversion member 40A disposed outward of the plurality of light-emitting parts 20 in a plan view. The outer perimeter wavelength conversion member 40A has a configuration similar to the wavelength conversion member 40 described above, and includes the phosphor layer 41, the light-diffusing layer 42, and the light-transmitting layer 43. A plurality of outer perimeter wavelength conversion members 40A are disposed to surround the plurality of light-emitting parts 20 and the plurality of wavelength conversion members 40 on the plurality of light-emitting parts 20 in a plan view. The second resin part 50 is disposed between an outer perimeter wavelength conversion member 40A and a wavelength conversion member 40 adjacent to the outer perimeter wavelength conversion member 40A.

The light-emitting part 20 is not disposed below the outer perimeter wavelength conversion members 40A. A portion (the outer perimeter part) of the first resin part 30 and the third resin part 60 are located below the outer perimeter wavelength conversion member 40A. The third resin part 60 covers the lateral surfaces of the first resin part 30 on the outer perimeter part 10C of the upper surface of the substrate 10.

There is no light-emitting part 20 below the outer perimeter wavelength conversion member 40A. Therefore, the light that is emitted by the light-emitting parts 20 positioned inward of the outer perimeter wavelength conversion members 40A in a plan view is shielded by the first, second, and third resin parts 30, 50, and 60, and is not easily incident on the outer perimeter wavelength conversion member 40A.

The light-emitting device 2 includes the outer perimeter wavelength conversion member 40A, so that a wavelength conversion member is disposed at the outer perimeter in a plan view, and the amount of the light-reflective member located at the outer perimeter is reduced. Therefore, compared to a light-emitting device in which only the light-reflective member is disposed at the outer perimeter, variation between the appearance of the region of the outer perimeter and the appearance of the inner region surrounded with the region of the outer perimeter is reduced, which allows the light-emitting device to have a good appearance when not emitting light.

### Third Embodiment

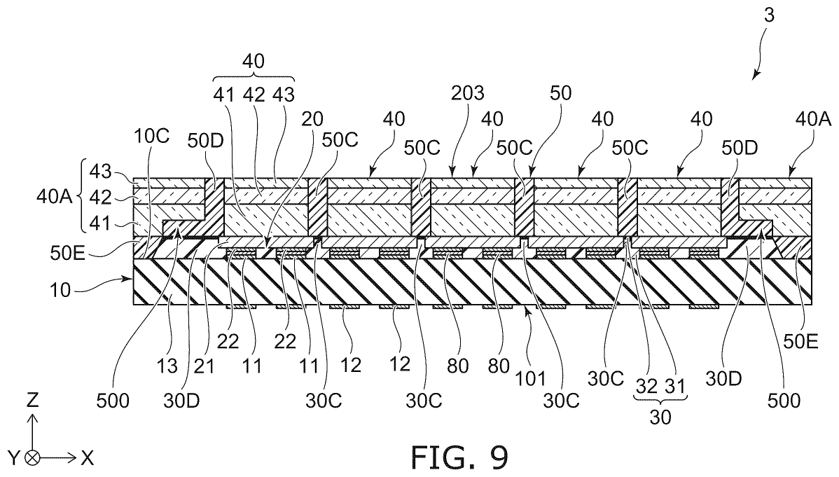

A light-emitting device 3 according to a third embodiment will now be described with reference to FIG. 9.

The light-emitting device 3 includes the first structure 101 and a second structure 203. The light-emitting device 3 differs from the light-emitting device 2 of the second embodiment mainly in that a recessed part 500 is formed in the outer perimeter wavelength conversion member 40A of the second structure 203, the adhesive layer 70 is not disposed between the second structure 203 and the first structure 101, and the wavelength conversion member 40 is directly bonded to the light-emitting part 20.

The first resin part 30 of the first structure 101 includes a first inner lateral part 30C positioned between adjacent ones of the plurality of light-emitting parts 20, and a first outer perimeter part 30D positioned outward of the plurality of light-emitting parts 20 in a plan view.

The second structure 203 includes the plurality of wavelength conversion members 40, and the second resin part 50 disposed between adjacent ones of the plurality of wavelength conversion members 40. The second resin part 50 includes a second inner lateral part 50C disposed on the first inner lateral part 30C of the first resin part 30, and a second outer perimeter part 50D disposed on the first outer perimeter part 30D of the first resin part 30.

Similarly to the second embodiment, the plurality of wavelength conversion members 40 include the outer perimeter wavelength conversion member 40A disposed outward of the plurality of light-emitting parts 20 in a plan view, and the light-emitting part 20 is not disposed below the outer perimeter wavelength conversion member 40A. A third resin part 50E covers the lateral surfaces of the first outer perimeter part 30D of the first resin part 30 on the outer perimeter part 10C of the upper surface of the substrate 10. The outer perimeter wavelength conversion member 40A is disposed on the third resin part 50E. According to the embodiment, the second inner lateral part 50C, the second outer perimeter part 50D, and the third resin part 50E are made of the same material, and are connected to each other.

First, as shown in FIG. 4B, the structure 100 that includes the substrate 10 and the light source part 103 is provided. As an example according to the embodiment, the light source part 103 includes 5×5 light-emitting parts 20. For example, the light source part 103 is manufactured as follows. First, a monolithic substrate in the wafer state is provided in which a plurality of planned light source portions, which will become the light source parts 103 after singulation, are connected. Each planned light source portion includes 5×5 light-emitting parts 20 and the element substrate 200. Then, the plurality of light source parts 103 can be obtained by singulating the monolithic substrate by cleaving. At this time, a wide margin is set in the cleaving region of the monolithic substrate so that the stress exerted in cleaving the monolithic substrate is less likely to affect the light-emitting parts 20. In other words, a wide space is obtained between the cleaving position of the monolithic substrate and light-emitting parts 20 adjacent to the cleaving position in a plan view.

Then, the first resin part 30 is disposed between the lower surface 200B of the element substrate 200 and the upper surface of the substrate 10. At this time, the width of the first outer perimeter part 30D disposed at the outer perimeter part of the lower surface 200B of the element substrate 200 is greater than the width of the first inner lateral part 30C positioned between the plurality of light-emitting parts 20 due to the margin set for cleaving the monolithic substrate. For example, the width of the first inner lateral part 30C is not less than 1 μm and not more than 30 μm, and the width of the first outer perimeter part 30D is not less than 50 μm and not more than 500 μm. Therefore, when the light-absorbing part 32 is formed at the upper surface side of the first resin part 30 by the laser light irradiation described above, the width of the light-absorbing part 32 of the first outer perimeter part 30D is greater than the width of the light-absorbing part 32 of the first inner lateral part 30C. Accordingly, in the appearance of the light-emitting device when viewed from the light-emitting surface side when not emitting light, the color of the light-absorbing part 32 of the first outer perimeter part 30D is highly noticeable, which may result in variation in color between the outer perimeter part and the inner lateral part of the light-emitting device.

The light-emitting device 3 according to the third embodiment includes the recessed part 500 below the outer perimeter wavelength conversion member 40A. With the recessed part 500 below the outer perimeter wavelength conversion member 40A, the width of the lower surface of the second outer perimeter part 50D is increased. More specifically, the width of the lower surface of the second outer perimeter part 50D disposed between the outer perimeter wavelength conversion member 40A and the wavelength conversion member 40 adjacent to the outer perimeter wavelength conversion member 40A is increased. Compared to when the recessed part 500 is not provided, a wider area of the upper surface of the first outer perimeter part 30D can be covered with the second outer perimeter part 50D. It is preferable that the second outer perimeter part 50D covers the entire surface of the upper surface of the light-absorbing part 32. With this structure, the color of the light-absorbing part 32 of the outer perimeter part when not emitting light can be less noticeable, and the light-emitting device 3 can have a good appearance when not emitting light. With the recessed part 500 located only below the outer perimeter wavelength conversion member 40A in the cross section shown in FIG. 9, that is, not located above the outer perimeter wavelength conversion member 40A, the width of the upper surface of the second outer perimeter part 50D and the width of the upper surface of the second inner lateral part 50C can be equal to each other. That is, having the recessed part 500 only below the outer perimeter wavelength conversion member 40A allows for increasing the width of the lower surface of the second outer perimeter part 50D without changing the width of the upper surface of the second outer perimeter part 50D. Accordingly, the widths of the second inner lateral part 50C and the second outer perimeter part 50D can be equal to each other in a plan view, and the color of the light-absorbing part 32 of the outer perimeter part is not highly noticeable when not emitting light. As a result, the light-emitting device 3 can have a good appearance when not emitting light.

Further, the volume of the second resin part 50 on the outer perimeter part of the first structure 101 is increased, which allows the light emitted by the light-emitting part 20 positioned at the outer side to be more easily reflected upward toward the light-emitting surface side by the second outer perimeter part 50D of the second resin part 50. Accordingly, the light that is emitted outside the light-emitting device 3 from the outer lateral surface of the outer perimeter wavelength conversion member 40A can be reduced.

According to the embodiment, the wavelength conversion member 40 is directly bonded to the light-emitting part 20. In other words, a bonding member or the like is not disposed between the wavelength conversion member 40 and the light-emitting part 20. This allows the light emitted from the light-emitting part 20 to be inhibited from propagating through the bonding member, spreading in the horizontal direction, and exiting toward the adjacent light-emitting part 20 side. As a result, the light-emitting device can have high contrast.

In the light-emitting device 3 shown in FIG. 9, the third resin part 50E is disposed outward of the first outer perimeter part 30D. The light-emitting device according to the embodiment does not necessarily include the third resin part 50E. In such a case, for example, the first outer perimeter part 30D reaches the outer lateral surface of the light-emitting device 3 instead of the third resin part 50E. Also, the upper surface of the first outer perimeter part 30D includes a region at which the light-absorbing part 32 is disposed, and a region on which the light-absorbing part 32 is not disposed. For example, in the upper surface of the first outer perimeter part 30D, the regions at which the light-absorbing part 32 is disposed are ring-shaped regions, each adjacent to corresponding ones of the light-emitting parts 20, located at the inner side, and the region at which the light-absorbing part 32 is not disposed is located outward of the regions at which the light-absorbing part 32 is disposed. In such a case, the second outer perimeter part 50D is disposed on the region at which the light-absorbing part 32 is disposed, and the outer perimeter wavelength conversion member 40A is disposed on the region at which the light-absorbing part 32 is not disposed.

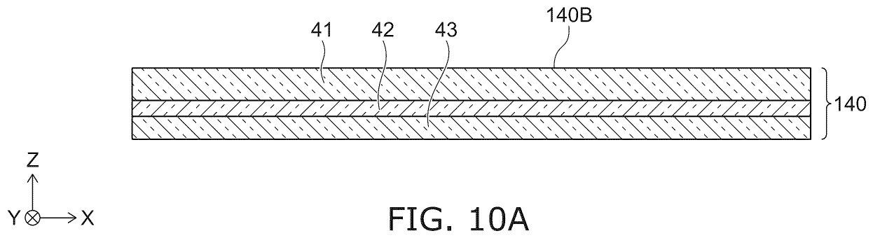

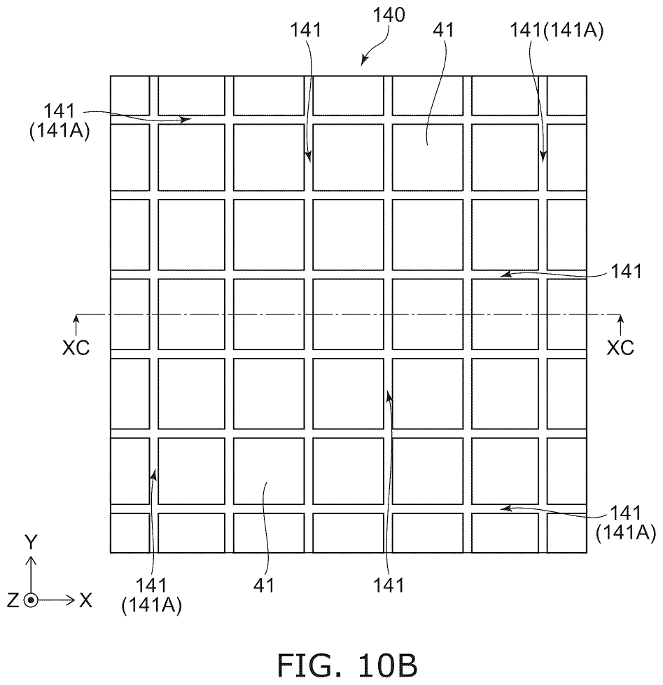

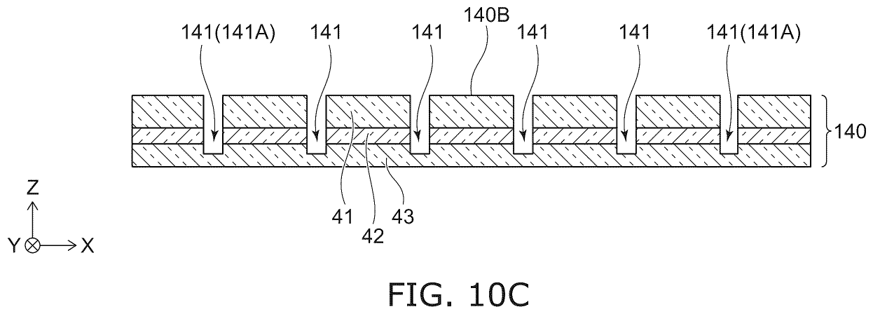

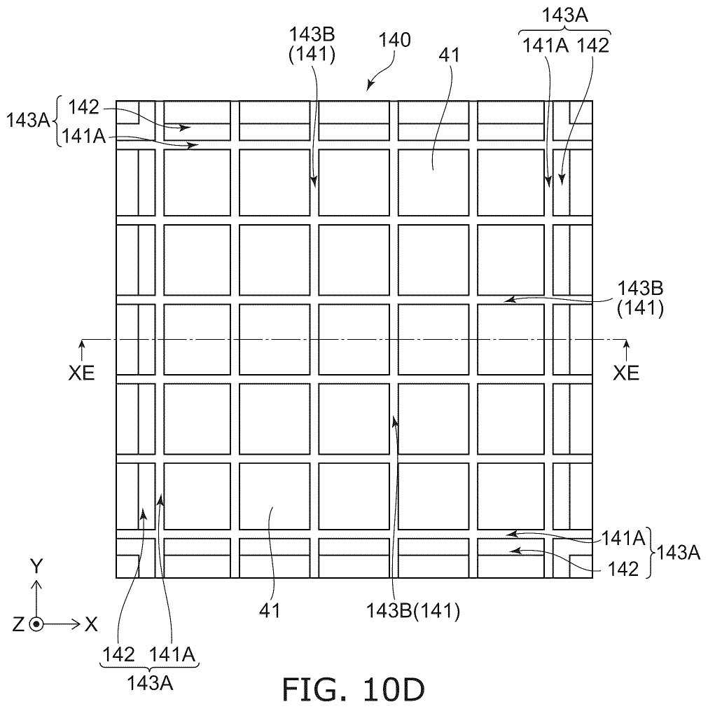

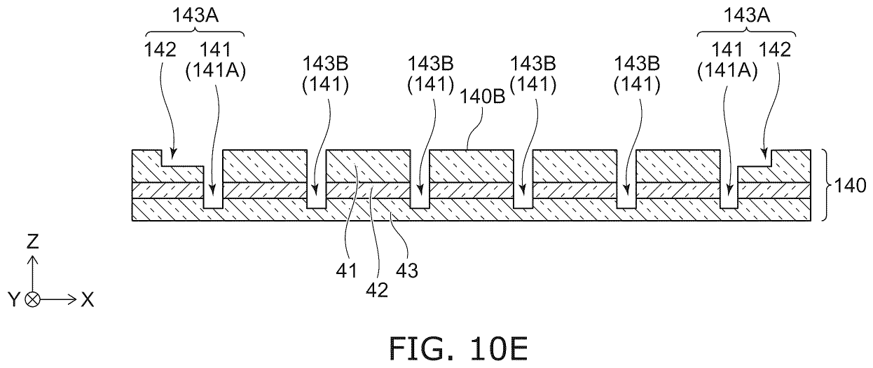

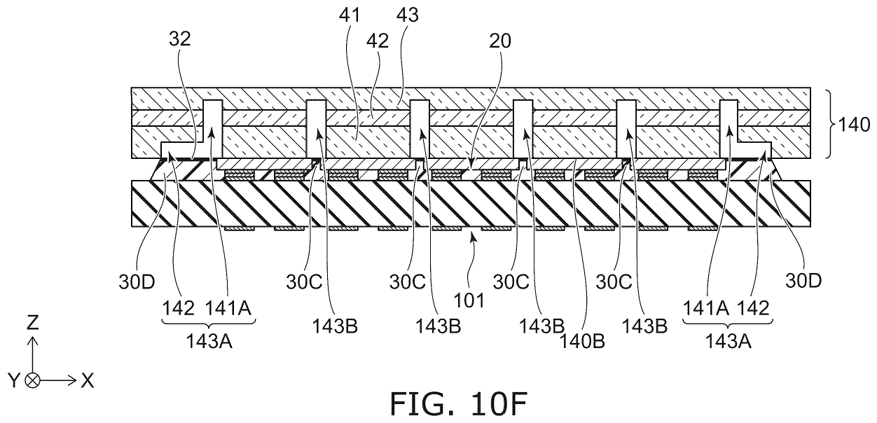

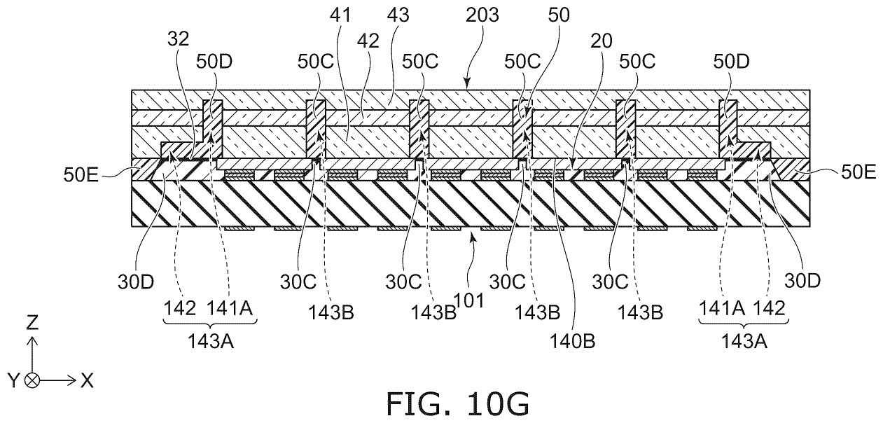

A method for manufacturing the light-emitting device according to the third embodiment will now be described with reference to FIGS. 10A to 10G.

As shown in FIG. 10G, the method for manufacturing the light-emitting device according to the third embodiment includes a step of disposing the second structure 203 on the first structure 101 obtained after the element substrate 200 is removed.

The step of disposing the second structure 203 includes providing the wavelength conversion sheet 140, forming a groove part in the wavelength conversion sheet 140, and disposing the second resin part 50 in the groove part.

In the providing the wavelength conversion sheet 140 as shown in FIG. 10A, the wavelength conversion sheet 140 that includes the phosphor layer 41, the light-transmitting layer 43, and the light-diffusing layer 42 positioned between the phosphor layer 41 and the light-transmitting layer 43 is provided. In the providing the wavelength conversion sheet 140, the resin material of the phosphor layer 41 is in the B-stage state, and the resin materials of the light-transmitting layer 43 and the light-diffusing layer 42 are in the C-stage state. The B-stage state of the resin material of the phosphor layer 41 is maintained until the resin material of the phosphor layer 41 is cured by a second heat treatment step described below. For example, the light-diffusing layer 42 and the light-transmitting layer 43 of the wavelength conversion sheet 140 that are in the C-stage state and formed to be a continuous body are obtained by bonding the uncured light-diffusing layer 42 and the uncured light-transmitting layer 43 and then performing a heat treatment. Subsequently, the phosphor layer 41 in the B-stage state is bonded to the light-diffusing layer 42 side, so that the wavelength conversion sheet 140 can be obtained. The wavelength conversion sheet 140 is supported by the supporting member so that the phosphor layer 41 is located relatively upward. The supporting member is not illustrated in FIG. 10A. The upper surface of the phosphor layer 41 is referred to as a first sheet surface 140B of the wavelength conversion sheet 140. The first sheet surface 140B faces the first structure 101 in the step of disposing the second structure 203 on the first structure 101.

The method for manufacturing the light-emitting device according to the embodiment includes a first heat treatment step in which the phosphor layer 41 of the wavelength conversion sheet 140 is heat-treated at a first condition. The resin material of the phosphor layer 41 after the first heat treatment step is in the B-stage state. By performing the first heat treatment step with respect to the wavelength conversion sheet 140, the hardness of the phosphor layer 41 can be increased while maintaining a predetermined tack force at the surface of the phosphor layer 41. Increasing the hardness of the phosphor layer 41 allows for, for example, when a groove part is formed by a blade in a later step, inhibiting the groove part from being crushed. The first heat treatment step also may be called a step of adjusting the hardness of the phosphor layer 41. By performing the first heat treatment step after the providing the wavelength conversion sheet 140, that is, after bonding the phosphor layer 41 and the light-diffusing layer 42, the phosphor layer 41 can be bonded to the light-diffusing layer 42 in a state in which the phosphor layer 41 has a tack force higher than that after the first heat treatment step; therefore, the adhesion between the phosphor layer 41 and the light-diffusing layer 42 can be increased. As a result, delamination and the like at the interface between the phosphor layer 41 and the light-diffusing layer 42 when forming the groove part can be reduced.

In the first heat treatment step, the first condition includes a first temperature and a first heating time. For example, the first temperature can be set to be not less than 80° C. and not more than 130° C., and the first heating time can be set to be not less than 10 minutes and not more than 120 minutes.

According to the embodiment, for example, the tack force of the resin material of the phosphor layer 41 after the first heat treatment step is not less than 20% and not more than 90% of the tack force of the resin material of the phosphor layer 41 before the first heat treatment step.

Then, as shown in FIGS. 10B and 10C, a groove part is formed in the wavelength conversion sheet 140. The forming the groove part in the wavelength conversion sheet 140 includes forming a plurality of first groove parts 141 in the wavelength conversion sheet 140 from the first sheet surface 140B side. As shown in FIG. 10B, the plurality of first groove parts 141 extend in the first and second directions X and Y in a plan view. As shown in FIG. 10C, the plurality of first groove parts 141 extend through the phosphor layer 41 and the light-diffusing layer 42 from the first sheet surface 140B and reach a portion of the light-transmitting layer 43. The bottoms of the first groove parts 141 are positioned lower than the interface between the light-diffusing layer 42 and the light-transmitting layer 43. Outermost first groove parts 141 of the plurality of first groove parts 141 in a plan view will be referred to as outer-perimeter first groove parts 141A.

As shown in FIGS. 10D and 10E, the forming the groove part in the wavelength conversion sheet 140 further includes forming a second groove part 142, which extends from the outer-perimeter first groove part 141A outward of the outer-perimeter first groove part 141A in a plan view, in the wavelength conversion sheet 140 at the first sheet surface 140B side. The depth from the first sheet surface 140B of the second groove part 142 is less than the depth from the first sheet surface 140B of the first groove part 141. The bottom of the second groove part 142 is positioned inside the phosphor layer 41.

The second groove part 142 extends in the first and second directions X and Y along the outer-perimeter first groove parts 141A. Second groove parts 142 that extend in the second direction Y is continuous with the outer-perimeter first groove part 141A in the first direction X. The second groove part 142 that extends in the first direction X is continuous with the outer-perimeter first groove part 141A in the second direction Y. Among the plurality of groove parts, an outer perimeter groove part 143A positioned at the outer perimeter in a plan view is made of the outer-perimeter first groove part 141A and the second groove part 142. Among the plurality of groove parts, an inner groove part 143B positioned inward of the outer perimeter groove part 143A in a plan view is made of the first groove part 141, and does not include the second groove part 142. The width of the opening of the outer perimeter groove part 143A at the first sheet surface 140B side is greater than the width of the opening of the inner groove part 143B at the first sheet surface 140B side.

For example, the first groove part 141 and the second groove part 142 can be formed by blade or laser processing.

The forming the first groove part 141 and the second groove part 142 is not limited to forming the second groove part 142 after the first groove part 141 is formed; the first groove part 141 may be formed after the second groove part 142 is formed, or the first groove part 141 and the second groove part 142 may be simultaneously formed.

After the first and second groove parts 141 and 142 are formed, the wavelength conversion sheet 140 is disposed on the first structure 101 as shown in FIG. 10F. In the disposing the wavelength conversion sheet 140 on the first structure 101, the wavelength conversion sheet 140 is disposed such that the phosphor layer 41 is positioned on the light-emitting part 20, the inner groove part 143B is positioned on the first inner lateral part 30C of the first resin part 30, and the outer perimeter groove part 143A is positioned on the first outer perimeter part 30D of the first resin part 30. The upper surface of the first outer perimeter part 30D faces the opening of the outer perimeter groove part 143A.

Then, the second heat treatment step is performed to cure the resin material of the phosphor layer 41 by heat-treating the resin material of the phosphor layer 41 at a second condition. By heating in the second heat treatment step, the resin material of the phosphor layer 41 softens from the B-stage state, and then is cured to be in the C-stage state. The light-diffusing layer 42 that is already in the C-stage state is not softened in the second heat treatment step. The phosphor layer 41 that is on the light-emitting part 20 is fixed by the second heat treatment step. As a result, the light-emitting part 20 and the phosphor layer 41 are directly bonded together. Also, the phosphor layer 41 and the light-diffusing layer 42 are fixed to each other. The second condition of the second heat treatment step includes a second temperature and a second heating time. For example, the second temperature can be set to be not less than 140° C. and not more than 160° C., and the second heating time can be set to be not less than 100 minutes and not more than 200 minutes.

The disposing the second structure 203 includes a process disposing a second resin part 50 in the outer perimeter groove part 143A and the inner groove part 143B as shown in FIG. 10G after the wavelength conversion sheet 140 is disposed on the first structure 101. For example, the second resin part 50 is disposed in the outer perimeter groove part 143A and the inner groove part 143B by causing a liquid resin material to flow into the outer perimeter groove part 143A and the inner groove part 143B using a mold, and then curing the resin material by heating. The second outer perimeter part 50D of the second resin part 50 is disposed in the outer perimeter groove part 143A to cover the entire surface of the upper surface of the light-absorbing part 32. A portion of the resin material described above covers the lateral surfaces of the first outer perimeter part 30D of the first resin part 30 as the third resin part 50E.

After the second resin part 50 is disposed, the step of disposing the second structure 203 includes removing a portion of the light-transmitting layer 43 positioned at the side opposite to the light-diffusing layer 42 by, for example, a polishing device or the like to expose the second resin part 50. As a result, as shown in FIG. 9, the second structure 203 that includes the plurality of wavelength conversion members 40 and the second resin part 50 disposed between the plurality of wavelength conversion members 40 is disposed on the first structure 101.

The step of disposing the second structure 203 may further include performing plasma processing of the wavelength conversion sheet 140 after the groove part is formed in the wavelength conversion sheet 140 and before the second resin part 50 is disposed in the groove part. This allows for improving the fillability of the second resin part 50 in the groove part. It is favorable to perform plasma processing of the wavelength conversion sheet 140 at the timing shown in FIG. 10F, specifically, after the wavelength conversion sheet 140 is disposed on the first structure 101 and before the second resin part 50 is disposed in the groove part. By performing the plasma processing directly before disposing the second resin part 50 in the groove part, variation in the fillability of the second resin part 50 in the groove part is reduced. In such a case, for example, plasma is irradiated from the upper side of the light-transmitting layer 43 in FIG. 10F to perform surface treatment of the opening vicinity of the groove part positioned at the outer lateral surface of the wavelength conversion sheet 140. This allows for improving the wettability at the opening vicinity of the groove part, so that the resin material to become the second resin part 50 flows more easily through the opening of the groove part. For example, polarized functional groups are formed at the surface of the resin member by performing plasma processing on a surface of a resin member. As a result, the affinity between the resin member and another resin material (e.g., the resin material to become the second resin part 50) is improved, and the wettability is improved. By performing the plasma treatment, organic substances contaminating the surface of the resin member is removed, which can improve the wettability of the surface of the resin member.

The method for manufacturing the light-emitting device according to the third embodiment may further include, before disposing the second structure 203 on the first structure 101 obtained after the element substrate 200 is removed, a step of removing a portion of the upper surface side of the first outer perimeter part 30D of the first resin part 30. As a result, the light-absorbing part 32 at the upper surface side of the first outer perimeter part 30D can be removed, so that the light-emitting device 3 can have a good appearance when not emitting light. For example, the portion of the upper surface side of the first outer perimeter part 30D can be removed by CO₂ laser processing, blade processing, spraying sublimating particles (e.g., solid carbon dioxide), spraying microparticles (e.g., micro-ice-jet machining), etc. When the step of removing the portion of the upper surface side of the first outer perimeter part 30D is performed, the recessed part 500 is not necessarily formed in the outer perimeter wavelength conversion member 40A.

### Modification

In the light-emitting devices according to the first to third embodiments, the first structure and the light source part include plurality of light-emitting parts. The light source part and the first structure may include one light-emitting part. That is, the light source part may include a single light-emitting part for a single element substrate. The first structure may include a substrate, one light-emitting part disposed at the upper surface of the substrate, and a first resin part that holds the light-emitting part and does not cover the upper surface of the light-emitting part.

Hereinabove, certain embodiments of the disclosure are described with reference to specific examples. However, the disclosure is not limited to these specific examples. All configurations practicable by an appropriate design modification by one skilled in the art based on the embodiments of the disclosure described above also are within the scope of the disclosure to the extent that the spirit of the disclosure is included. Various modifications and alterations within the spirit of the disclosure will be readily apparent to those skilled in the art. All such modifications and alterations should therefore be seen as within the scope of the disclosure.

What is claimed is:

1. A method for manufacturing a light-emitting device, the method comprising:
providing a structure comprising:
a substrate comprising a plurality of positive and negative wiring parts at an upper surface of the substrate, and
a light source part disposed on the substrate, the light source part comprising:
an element substrate, and
a plurality of light-emitting parts, each of the light-emitting parts comprising:
a semiconductor structure including a first surface facing the element substrate and a second surface positioned at a side opposite to the first surface, and
positive and negative electrode parts disposed on the second surface of the semiconductor structure, each of the positive and negative electrode parts being electrically connected with a corresponding one of the positive and negative wiring parts of the substrate;
providing a mold comprising an upper mold and a lower mold;
disposing a first resin part between the upper surface of the substrate and the second surfaces of the semiconductor structures, which comprises:
disposing the structure between the upper mold and the lower mold,
supplying a resin material into the mold in a state in which an upper surface of the element substrate is covered with a covering member,
curing the resin material, and
after the curing, removing the covering member; and
removing the element substrate from the light source part.

2. The method according to claim 1, wherein:
the disposing of the first resin part comprises removing a portion of the first resin part, the portion being located on the upper surface of the element substrate.

3. The method according to claim 2, wherein:
the portion of the first resin part is removed by wet blasting in the removing of the portion of the first resin part.

4. The method according to claim 1, further comprising:
after removing the element substrate, removing another portion of the first resin part and a portion of the semiconductor structure at the first surface side.

5. The method according to claim 1, wherein:
the element substrate is a sapphire substrate;
the semiconductor structure comprises gallium nitride; and
the removing of the element substrate from the light source part comprises irradiating a laser light from the upper surface side of the element substrate toward the first surface of the semiconductor structure to decompose the gallium nitride at the first surface into nitrogen and gallium to cause a gas generated in the decomposition to detach the element substrate from a portion of the first resin part.

6. The method according to claim 1, wherein:
a first structure is obtained after the step of removing the element substrate; and the method further comprises:
disposing a second structure on the first surfaces of the semiconductor structures included in the first structure, wherein the second structure comprises:
a plurality of wavelength conversion members, and
a second resin part disposed between adjacent ones of the plurality of wavelength conversion members, the second resin part holding the plurality of wavelength conversion members.

7. The method according to claim 6, wherein:
each of the wavelength conversion members comprises:
a phosphor layer disposed on the first surface,
a light-diffusing layer disposed on the phosphor layer, and
a light-transmitting layer disposed on the light-diffusing layer and having an upper surface.

8. The method according to claim 7, wherein:
the second resin part covers the upper surfaces of the light-transmitting layers; and the method further comprises:
after disposing the second structure on the first surfaces, disposing a third resin part on the substrate, the third resin part covering the first and second structure bodies; and
simultaneously removing the third resin part, a portion of the second resin part covering the upper surfaces of the light-transmitting layers, and portions of the light-transmitting layers at the upper surface side.

9. The method according to claim 6, wherein:
the disposing of the second structure comprises disposing the second structure on the first surfaces via an adhesive layer; and
the adhesive layer is disposed to be continuous and to bend so as to be disposed on the upper surface of the substrate, lateral surfaces of the first resin part, an upper surface of the first resin part, and the first surfaces of the semiconductor structures by spraying.

10. The method according to claim 1, wherein:
a Shore hardness of the first resin part after curing is not less than HSD 70; and
a difference between a linear expansion coefficient of the first resin part after curing and a linear expansion coefficient of the semiconductor structure is not more than 30 ppm.

11. The method according to claim 1, wherein:
a first structure is obtained after the step of removing the element substrate; and the method further comprises:
disposing a second structure on the first structure, wherein:
the second structure comprises:
a plurality of wavelength conversion members, and
a second resin part disposed between adjacent ones of the plurality of wavelength conversion members, the second resin part comprising:
a second inner lateral part disposed on a first inner lateral part of the first resin part, the first inner lateral part being positioned between adjacent ones of the plurality of light-emitting parts, and
a second outer perimeter part disposed on a first outer perimeter part of the first resin part, the first outer perimeter part being positioned outward of the plurality of light-emitting parts, wherein:
the second outer perimeter part covers an entirety of an upper surface of the first outer perimeter part.

12. The method according to claim 11, wherein:
the disposing of the second structure comprises:
providing a wavelength conversion sheet,
forming a groove part in the wavelength conversion sheet, and
disposing the second resin part in the groove part; and
the forming of the groove part comprises:
forming a plurality of first groove parts in the wavelength conversion sheet at a first sheet surface side facing the first structure, and
forming a second groove part at the first sheet surface side, the second groove part being shallower than the first groove parts and extending outward from an outer-perimeter first groove part, the outer-perimeter first groove part being one of outermost first groove parts of the plurality of first groove parts.

13. The method according to claim 12, wherein:
the disposing of the second structure further comprises, after forming the groove part and before disposing the second resin part, performing plasma processing of the wavelength conversion sheet.

14. A light-emitting device, comprising:
a first structure comprising:
a substrate,
a plurality of light-emitting parts disposed on an upper surface of the substrate, each of the plurality of light-emitting parts having an upper surface, and
a first resin part holding the plurality of light-emitting parts and arranged such that the upper surfaces of the light-emitting parts are exposed from the first resin part, the first resin part comprising:
a light-reflecting part having high light reflectivity, and
a light-absorbing part disposed on the light-reflecting part, wherein a light absorbance of the light-absorbing part is higher than a light absorbance of the light-reflecting part; and
a second structure comprising:
a plurality of wavelength conversion members each disposed on a respective one of the light-emitting parts, and
a second resin part disposed on the light-absorbing part between adjacent ones of the plurality of wavelength conversion members.

15. The light-emitting device according to claim 14, wherein:
each of the light-emitting parts comprises:
a semiconductor structure, and
positive and negative electrode parts disposed on a lower surface of the semiconductor structure.

16. The light-emitting device according to claim 14, wherein:
the upper surfaces of the light-emitting parts and an upper surface of the first resin part are coplanar at an upper surface of the first structure.

17. The light-emitting device according to claim 14, further comprising:
a third resin part covering at least lateral surfaces of the first resin part and a portion of the upper surface of the substrate.

18. The light-emitting device according to claim 14, further comprising:
a light-transmissive adhesive layer continuously covering the upper surfaces of the light-emitting parts and an upper surface of the light-absorbing part; wherein:
a thickness of the adhesive layer is not less than 1 μm and not more than 15 μm.

19. The light-emitting device according to claim 18, wherein:
the adhesive layer further covers an upper surface of the first resin part positioned outward of the plurality of light-emitting parts in a plan view; and
the light-absorbing part is further disposed below the adhesive layer covering the upper surface of the first resin part positioned outward of the plurality of light-emitting parts.

20. The light-emitting device according to claim 18, wherein:
the adhesive layer is disposed to be continuous and to bend so as to be disposed on a portion of the upper surface of the substrate, lateral surfaces of the first structure, and an upper surface of the first structure.

21. The light-emitting device according to claim 14, wherein:
the first resin part contains a metal oxide.

22. The light-emitting device according to claim 14, wherein:
a distance between two adjacent light-emitting parts among the plurality of light-emitting parts is not less than 1 μm and not more than 15 μm.

23. The light-emitting device according to claim 14, wherein:
an outer edge of the wavelength conversion member is positioned inward of an outer edge of the light-emitting part in a plan view.

24. The light-emitting device according to claim 14, further comprising:
bonding members each bonding a corresponding one of positive and negative electrode parts of the light-emitting part and a corresponding one of positive and negative wiring parts of the substrate; wherein:
an area of each of the bonding members in contact with the corresponding one of the electrode parts is not less than 70% of an area of the corresponding one of the electrode parts in a plan view.
